(19) United States
(12) Patent Application Publication
(10) Pub. No.: US 2023/0207598 A1
(43) Pub. Date: Jun. 29, 2023

(54) PHOTOELECTRIC CONVERTER AND IMAGING DEVICE

(71) Applicants: SONY GROUP CORPORATION, Tokyo (JP); SONY SEMICONDUCTOR SOLUTIONS CORPORATION, Kanagawa (JP)

(72) Inventors: Osamu ENOKI, Kanagawa (JP); Masato KANNO, Tokyo (JP); Chiaki TAKAHASHI, Tokyo (JP); Chika SUGIMURA, Kanagawa (JP); Yosuke SAITO, Kanagawa (JP)

(21) Appl. No.: 17/928,862

(22) PCT Filed: May 28, 2021
(86) PCT No.: PCT/JP2021/020411

§ 371 Date: Nov. 30, 2022

(30) Foreign Application Priority Data
Jun. 5, 2020 (JP) 2020-098871
May 27, 2021 (JP) 2021-089437

(51) Int. Cl. H01L 27/146; H10K 30/81; H10K 39/32; H10K 30/10

(52) U.S. Cl. CPC H01L 27/14634; H01L 27/14636; H01L 27/14603; H01L 27/14612; H10K 30/81; H10K 39/32; H10K 30/10

(57) ABSTRACT

A photoelectric converter includes: a first electrode; a second electrode; a first photoelectric conversion layer; a second photoelectric conversion layer; a first buffer layer; and a second buffer layer. The second electrode is disposed to be opposed to the first electrode. The first photoelectric conversion layer is provided between the first electrode and the second electrode. The first photoelectric conversion layer includes a first dye material and a first carrier transport material. The second photoelectric conversion layer is stacked on the second electrode side of the first photoelectric conversion layer between the first electrode and the second electrode. The second photoelectric conversion layer includes a second dye material and a second carrier transport material. The second dye material has a light absorption waveform different from a light absorption waveform of the first dye material. The first buffer layer has a first electrical conduction type. The first buffer layer is provided between the first electrode and the first photoelectric conversion layer. The second buffer layer has a second electrical conduction type different from the first electrical conduction type. The second buffer layer is provided between the second electrode and the second photoelectric conversion layer.

### TECHNICAL FIELD

The present disclosure relates, for example, to a photoelectric converter in which an organic material is used and an imaging device including this photoelectric converter.

### BACKGROUND ART

For example, PTL 1 discloses a solid-state imaging element having sensitivity to the whole visible light wavelengths by mixing two types of light absorbing materials.

### CITATION LIST

### Patent Literature

PTL 1: Japanese Unexamined Patent Application Publication No. 2013-254840

### SUMMARY OF THE INVENTION

Incidentally, a photoelectric converter used as an imaging element is requested to have higher afterimage characteristics.

It is desirable to provide a photoelectric converter and an imaging device that are each allowed to have improved afterimage characteristics.

A photoelectric converter includes: a first electrode; a second electrode; a first photoelectric conversion layer; a second photoelectric conversion layer; a first buffer layer; and a second buffer layer. The second electrode is disposed to be opposed to the first electrode. The first photoelectric conversion layer is provided between the first electrode and the second electrode. The first photoelectric conversion layer includes a first dye material and a first carrier transport material. The second photoelectric conversion layer is stacked on the second electrode side of the first photoelectric conversion layer between the first electrode and the second electrode. The second photoelectric conversion layer includes a second dye material and a second carrier transport material. The second dye material has a light absorption waveform different from a light absorption waveform of the first dye material. The first buffer layer has a first electrical conduction type. The first buffer layer is provided between the first electrode and the first photoelectric conversion layer. The second buffer layer has a second electrical conduction type different from the first electrical conduction type. The second buffer layer is provided between the second electrode and the second photoelectric conversion layer.

An imaging device according to an embodiment of the present disclosure includes the one or more photoelectric converters according to the embodiment of the present disclosure described above for each of a plurality of pixels.

The photoelectric converter according to the embodiment of the present disclosure and the imaging device according to the embodiment are each provided with the first photoelectric conversion layer and the second photoelectric conversion layer. The first photoelectric conversion layer and the second photoelectric conversion layer are stacked between the first electrode and the second electrode. The first photoelectric conversion layer includes the first dye material and the first carrier transport material. The second photoelectric conversion layer includes the second dye material and the second carrier transport material. The second dye material has the light absorption waveform different from that of the first dye material. This reduces the thickness of the photoelectric conversion layer.

### BRIEF DESCRIPTION OF DRAWING

FIG. 1 is a cross-sectional schematic diagram illustrating a configuration of a photoelectric converter according to an embodiment of the present disclosure.

FIG. 2 is a diagram illustrating an example of an energy level of each of layers of the photoelectric converter illustrated in FIG. 1.

FIG. 3 is a diagram illustrating another example of the configuration and the energy level of each of the layers of the photoelectric converter according to the embodiment of the present disclosure.

FIG. 4 is a block diagram illustrating an overall configuration of an imaging element according to an embodiment of the present disclosure.

FIG. 5 is a cross-sectional schematic diagram illustrating an example of a schematic configuration of the imaging element illustrated in FIG. 4.

FIG. 6 is an equivalent circuit diagram of an organic photoelectric conversion section illustrated in FIG. 5.

FIG. 7 is an equivalent circuit diagram of an inorganic photoelectric conversion section illustrated in FIG. 5.

FIG. 8 is a cross-sectional schematic diagram illustrating a configuration of a photoelectric converter according to a modification example 1 of the present disclosure.

FIG. 9 is a cross-sectional schematic diagram illustrating a configuration of a photoelectric converter according to a modification example 2 of the present disclosure.

FIG. 10 is a cross-sectional schematic diagram illustrating a configuration of a photoelectric converter according to a modification example 3 of the present disclosure.

FIG. 11 is a cross-sectional schematic diagram illustrating a configuration of a photoelectric converter according to a modification example 4 of the present disclosure.

FIG. 12A is a cross-sectional schematic diagram illustrating an example of a schematic configuration of an imaging element according to a modification example 5 of the present disclosure.

FIG. 12B is a plane schematic diagram illustrating an example of a pixel configuration of an imaging device including the imaging element illustrated in FIG. 12A.

FIG. 13 is a block diagram illustrating a configuration example of an electronic apparatus including the imaging element illustrated in FIG. 4 or another diagram.

FIG. 14 is a view depicting an example of a schematic configuration of an endoscopic surgery system.

FIG. 15 is a block diagram depicting an example of a functional configuration of a camera head and a camera control unit (CCU).

FIG. 16 is a block diagram depicting an example of schematic configuration of a vehicle control system.

FIG. 17 is a diagram of assistance in explaining an example of installation positions of an outside-vehicle information detecting section and an imaging section.

### MODES FOR CARRYING OUT THE INVENTION

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.
1. Embodiment (an example of a photoelectric converter in which two photoelectric conversion layers (a first layer and a second layer) are stacked)
1-1. Configuration of Photoelectric Converter
1-2. Configuration of Imaging Element
1-3. Workings and Effects
2. Modification Examples
2-1. Modification Example 1 (an example in which a second layer and a first layer are stacked in this order from a lower electrode side)
2-2. Modification Example 2 (an example in which a first layer is sandwiched by two second layers)
2-3. Modification Example 3 (an example in which three photoelectric conversion layers (a first layer, a second layer, and a third layer) are stacked)
2-4. Modification Example 4 (an example in which a first layer that detects visible light and a second layer that detects IR light are stacked)
2-5. Modification Example 5 (an example of an imaging element including a lower electrode including a plurality of electrodes)
3. Application Example
4. Practical Application Examples
5. Working Examples

### 1. EMBODIMENT

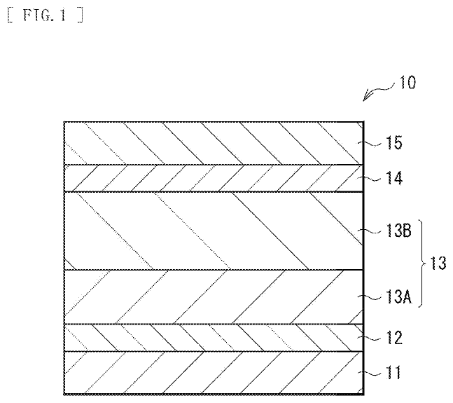

FIG. 1 schematically illustrates an example of a cross-sectional configuration of a photoelectric converter (photoelectric converter 10) according to an embodiment of the present disclosure. The photoelectric converter 10 is used for each of pixels (unit pixels P) in an imaging element (imaging element 1; see, for example, FIG. 4) such as a CMOS (Complementary Metal Oxide Semiconductor) image sensor used, for example, for an electronic apparatus such as a digital still camera or a video camera. In the photoelectric converter 10 according to the present embodiment, a lower electrode 11, a p buffer layer 12, a photoelectric conversion layer 13, an n buffer layer 14, and an upper electrode 15 are stacked in this order. In the photoelectric conversion layer 13, a first layer 13A and a second layer 13B are stacked in this order. The first layer 13A and the second layer 13B include dye materials and carrier transport materials. The dye materials have light absorption waveforms different from each other.

### 1-1. Configuration of Photoelectric Converter

The photoelectric converter 10 absorbs light corresponding, for example, to a portion or all of the wavelengths in the visible light region of 400 nm or more and 760 nm or less and generates an electron-hole pair (exciton). The photoelectric converter 10 reads out, for example, the hole of an electron-hole pair generated through photoelectric conversion in the imaging element 1 described below from the lower electrode 11 side as signal charge. The following describes a configuration, a material, and the like of each section by using, as an example, a case where a hole is read out as signal charge.

The lower electrode 11 includes, for example, an electrically conductive film having light transmissivity. Examples of a material included in the lower electrode 11 include an indium tin oxide including indium tin oxide (ITO), In₂O₃ to which tin (Sn) is added as a dopant, crystalline ITO, and amorphous ITO. In addition to the materials described above, a tin oxide (SnO₂)-based material to which a dopant is added or a zinc oxide-based material to which a dopant is added may be used as a material included in the lower electrode 11. Examples of the zinc oxide-based material include an aluminum zinc oxide (AZO) to which aluminum (Al) is added as a dopant, a gallium zinc oxide (GZO) to which gallium (Ga) is added, a boron zinc oxide to which boron (B) is added, and an indium zinc oxide (IZO) to which indium (In) is added. In addition, CuI, InSbO₄, ZnMgO, CuInO₂, MgIN₂O₄, CdO, ZnSnO₃, TiO₂, or the like may be used as a material included in the lower electrode 11. Further, a spinel oxide or an oxide having a YbFe₂O₄ structure may be used. It is to be noted that the lower electrode 11 formed by using any of the materials as described above generally has a high work function and functions as an anode electrode.

The p buffer layer 12 functions as a so-called electron block layer that selectively transports a hole of electric charge generated by the photoelectric conversion layer 13 to the lower electrode 11 and blocks the movement of an electron to the lower electrode 11 side. It is possible to form the p buffer layer 12 by using, for example, a material having a hole transporting property. The p buffer layer 12 has, for example, a thickness of 0.5 nm or more and 100 nm or less. Preferably, the p buffer layer 12 has a thickness of 1 nm or more and 50 nm or less. More preferably, the p buffer layer 12 has a thickness of 3 nm or more and 20 nm or less.

The photoelectric conversion layer 13 converts light energy to electric energy. The photoelectric conversion layer 13 absorbs, for example, pieces of light having a portion or all of the wavelengths in the visible light region of 400 nm or more and 760 nm or less. The photoelectric conversion layer 13 includes, for example, two or more types of organic materials each of which functions as a p-type semiconductor or an n-type semiconductor. The photoelectric conversion layer 13 has a junction surface (p/n junction surface) between the p-type semiconductor and the n-type semiconductor in the layer. The p-type semiconductor relatively functions as an electron donor and the n-type semiconductor relatively functions as an electron acceptor. The photoelectric conversion layer 13 provides a field where excitons generated upon light absorption are separated into electrons and holes. Specifically, the excitons are separated into electrons and holes at the interface (p/n junction surface) between the electron donor and the electron acceptor.

In the photoelectric conversion layer 13 according to the present embodiment, the first layer 13A and the second layer 13B having light absorption waveforms different from each other are directly stacked in this order from the lower electrode 11 side. The first layer 13A corresponds to a specific example of a “first photoelectric conversion layer” according to the present disclosure and the second layer 13B corresponds to a specific example of a “second photoelectric conversion layer” according to the present disclosure. The first layer 13A and the second layer 13B have, for example, the following configurations.

For example, it is possible to form each of the first layer 13A and the second layer 13B by using two types of organic materials. The two types of organic materials are a dye material and a so-called electron transport material. The dye material photoelectrically converts light in a predetermined wavelength region and transmits pieces of light in the other wavelength regions. The electron transport material relatively functions as an electron donor. It is preferable that the dye material further have a hole transporting property that causes the dye material to relatively function as an electron donor.

In addition, for example, it is possible to form each of the first layer 13A and the second layer 13B by using three types of organic materials including a dye material, a so-called electron transport material, and a so-called hole transport material. The dye material photoelectrically converts light in a predetermined wavelength region and transmits pieces of light in the other wavelength regions. The electron transport material relatively functions as an electron acceptor. The hole transport material relatively functions as an electron donor.

The respective dye materials included in the first layer 13A and the second layer 13B have light absorption waveforms differ from each other. For example, the dye material (corresponding to a “first dye material” according to the present disclosure) included in the first layer 13A has the peak of the maximum absorption in the wavelength range of 400 nm or more and 760 nm or less. The dye material included in the first layer 13A has a light absorption waveform, for example, in the wavelength region of 400 nm or more and 500 nm or less corresponding to blue. For example, the dye material (corresponding to a “second dye material” according to the present disclosure) included in the second layer 13B has the peak of the maximum absorption in the wavelength range of 400 nm or more and 760 nm or less. The dye material included in the second layer 13B has absorption waveforms, for example, in the wavelength regions of 500 nm or more and 760 nm or less corresponding to green and red. This causes the first layer 13A to absorb light in the wavelength region of the 400 nm or more and 500 nm or less corresponding to blue and causes the second layer 13B to absorb pieces of light in the wavelength regions of 500 nm or more and 760 nm or less corresponding to green and red.

It is to be noted that the respective absorption wavelengths of the first layer 13A and the second layer 13B are not limited to the above. For example, the first layer 13A may absorb pieces of light in the wavelength regions of 500 nm or more and 760 nm or less corresponding to green and red and the second layer 13B may absorb light in the wavelength region of 400 nm or more and 500 nm or less corresponding to blue. In that case, a dye material having absorption waveforms, for example, in the wavelength regions of 500 nm or more and 760 nm or less corresponding to green and red is used for the first layer 13A. A dye material having a light absorption waveform, for example, in the wavelength region of 400 nm or more and 500 nm or less corresponding to blue is used for the second layer 13B.

Further, it is preferable that the dye materials included in the first layer 13A and the second layer 13B have ionization potentials that are substantially the same as each other. Alternatively, it is preferable that the dye material included in the first layer 13A have a shallower ionization potential than the ionization potential of the dye material included in the second layer 13B.

It is preferable that the electron transport materials included in the first layer 13A and the second layer 13B have Lowest Unoccupied Molecular Orbital (LUMO) levels which are substantially the same as each other. Specifically, it is preferable that the electron transport material (corresponding to a “first electron transport material” according to the present disclosure) included in the first layer 13A and the electron transport material (corresponding to a “second electron transport material” according to the present disclosure) included in the second layer 13B be the same materials. Alternatively, it is preferable that the first electron transport material have a shallower LUMO level than the LUMO level of the second electron transport material. Examples of the first electron transport material and the second electron transport material include fullerenes or derivatives thereof including a C₆₀ fullerene and a C₇₀ fullerene.

It is preferable that the hole transport materials included in the first layer 13A and the second layer 13B have ionization potentials that are substantially the same as each other. Specifically, it is preferable that the hole transport material (corresponding to a “first hole transport material” according to the present disclosure) included in the first layer 13A and the hole transport material (corresponding to a “second hole transport material” according to the present disclosure) included in the second layer 13B be the same materials. Alternatively, it is preferable that the first hole transport material have a shallower ionization potential than the ionization potential of the second hole transport material.

Further, in a case where the first layer 13A and the second layer 13B are each formed by using two types of organic materials including a dye material and an electron transport material as described above, it is preferable that the energy levels of the first layer 13A and the second layer 13B have a relationship, for example, as illustrated in FIG. 2. Specifically, it is preferable that the first layer 13A and the second layer 13B each have, for example, an ionization potential of 6 eV or less. In other words, it is preferable that the respective ionization potentials of the first layer 13A and the second layer 13B be 6 eV or the first layer 13A and the second layer 13B have shallower ionization potentials. Further, it is preferable that the difference between the ionization potentials of the first layer 13A and the second layer 13B adjacent to each other be 0.2 eV or less. In addition, it is preferable that the ionization potential of the first layer 13A be less than the ionization potential of the second layer 13B. In other words, it is preferable that the difference between the ionization potentials of the first layer 13A and the second layer 13B adjacent to each other be 0.2 eV or less. In addition, it is preferable that the ionization potential of the first layer 13A be shallower than the ionization potential of the second layer 13B. This makes it possible to efficiently transport the hole of an electron-hole pair generated through photoelectric conversion by the second layer 13B to the lower electrode 11. The hole serves as signal charge. In addition, it is preferable that the difference in electron affinity between the first layer 13A and the second layer 13B adjacent to each other be 0.2 eV or less. In other words, it is preferable that the difference between the LUMO levels of the first layer 13A and the second layer 13B adjacent to each other be 0.2 eV or less. This makes it possible to efficiently transport the electron of an electron-hole pair generated through photoelectric conversion by the second layer 13B to the upper electrode 15.

Further, one of the first layer 13A or the second layer 13B may be formed by using two types of organic materials and the other of the first layer 13A or the second layer 13B may be formed by three types of organic materials. In that case, a hole transport material having light transmissivity tends to have a greater ionization potential than that of a dye material having a hole transporting property. For this reason, it is preferable that the layer including three types of organic materials be provided on the n buffer layer 14 side. In other words, in a case where one of the first layer 13A or the second layer 13B is formed by using two types of organic materials and the other of the first layer 13A or the second layer 13B is formed by using three types of organic materials, it is preferable that the first layer 13A to be provided on the p buffer layer 12 side be formed by using two types of organic materials and the second layer 13B to be provided on then buffer layer 14 side be formed by using three types of organic materials.

In the configuration described above, the first layer 13A has, for example, a thickness of 50 nm or more and 350 nm or less. Preferably, the first layer 13A has a thickness of 50 nm or more and 250 nm or less. The second layer 13B has, for example, a thickness of 50 nm or more and 350 nm or less. Preferably, the second layer 13B has a thickness of 50 nm or more and 250 nm or less. The photoelectric conversion layer 13 including the first layer 13A and the second layer 13B has, for example, a thickness of 100 nm or more and 700 nm or less. Preferably, the photoelectric conversion layer 13 has a thickness of 100 nm or more and 500 nm or less.

The n buffer layer 14 functions as a so-called hole block layer that selectively transports an electron of electric charge generated by the photoelectric conversion layer 13 to the upper electrode 15 and blocks the movement of a hole to the upper electrode 15 side. It is possible to form the n buffer layer 14 by using, for example, a material having an electron transporting property. The n buffer layer 14 has, for example, a thickness of 0.5 nm or more and 100 nm or less. Preferably, the n buffer layer 14 has a thickness of 1 nm or more and 50 nm or less. More preferably, the n buffer layer 14 has a thickness of 3 nm or more and 20 nm or less.

It is possible to form the p buffer layer 12, the photoelectric conversion layer 13 (the first layer 13A and the second layer 13B), and the n buffer layer 14 described above by using, for example, a vacuum evaporation method, for example. In addition, it is possible to form the p buffer layer 12, the photoelectric conversion layer 13 (the first layer 13A and the second layer 13B), and then buffer layer 14 by using, for example, spin coating technology, printing technology, or other technology.

The upper electrode 15 includes an electrically conductive film having light transmissivity as with the lower electrode 11. In the imaging element 1 in which the photoelectric converter 10 is used as the unit pixel P, the upper electrode 15 may be separated for each of the unit pixels P or the upper electrode 15 may be formed as an electrode common to the respective unit pixels P. The upper electrode 15 has, for example, a thickness of 10 nm or more and 200 nm or less.

In the photoelectric converter 10 according to the present embodiment, light entering the photoelectric converter 10 from the upper electrode 15 side is absorbed by the first layer 13A and the second layer 13B included in the photoelectric conversion layer 13. Excitons generated by this move to the interface between an electron donor and an electron acceptor respectively included in the first layer 13A and the second layer 13B and undergo exciton separation. In other words, the excitons are dissociated into electrons and holes. The electric charge (electrons and holes) generated here is transported to different electrodes by diffusion due to a difference in carrier concentration or by an internal electric field due to a difference in work functions between an anode (the lower electrode 11 here) and a cathode (the upper electrode 15 here) and are detected as a photocurrent. In addition, the application of a potential between the lower electrode 11 and the upper electrode 15 makes it possible to control directions in which electrons and holes are transported.

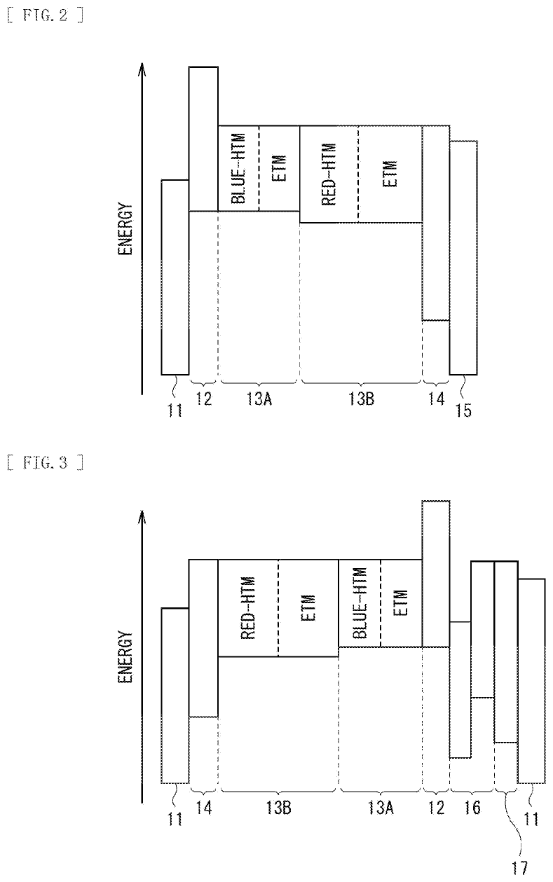

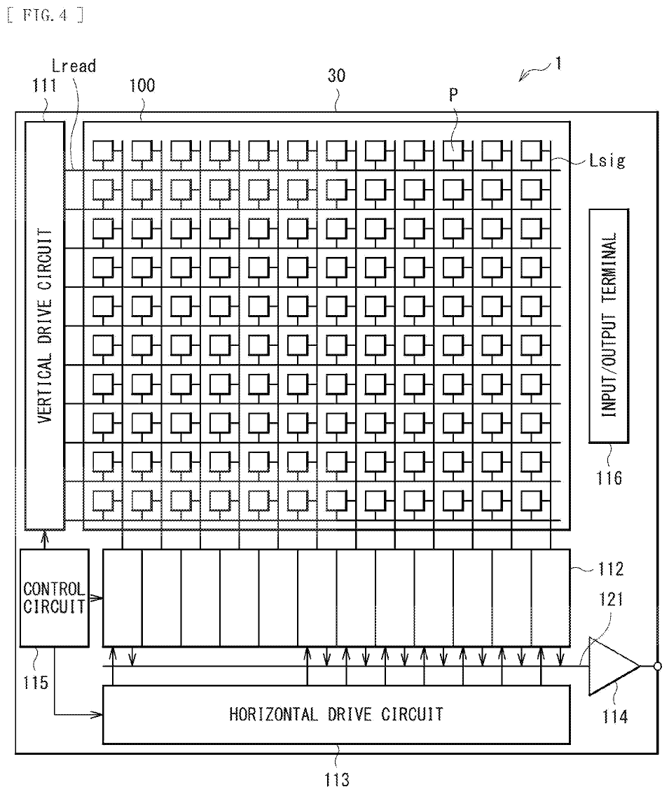

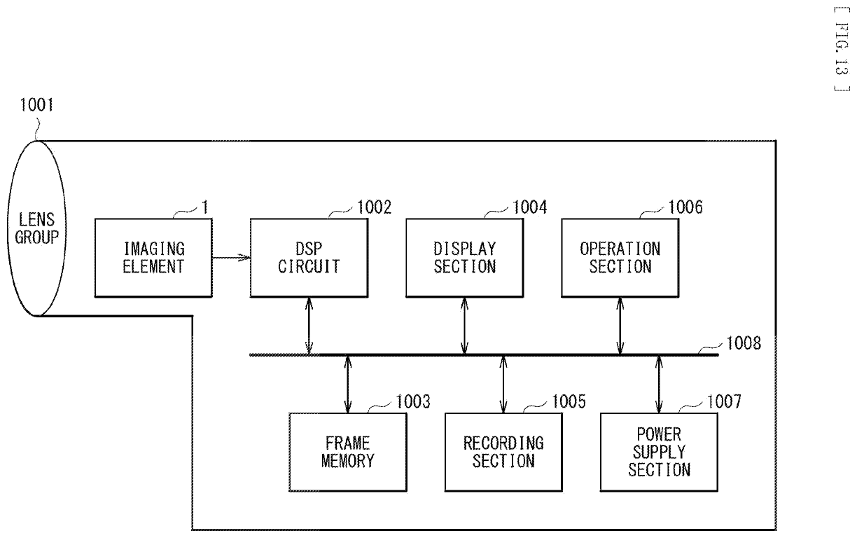

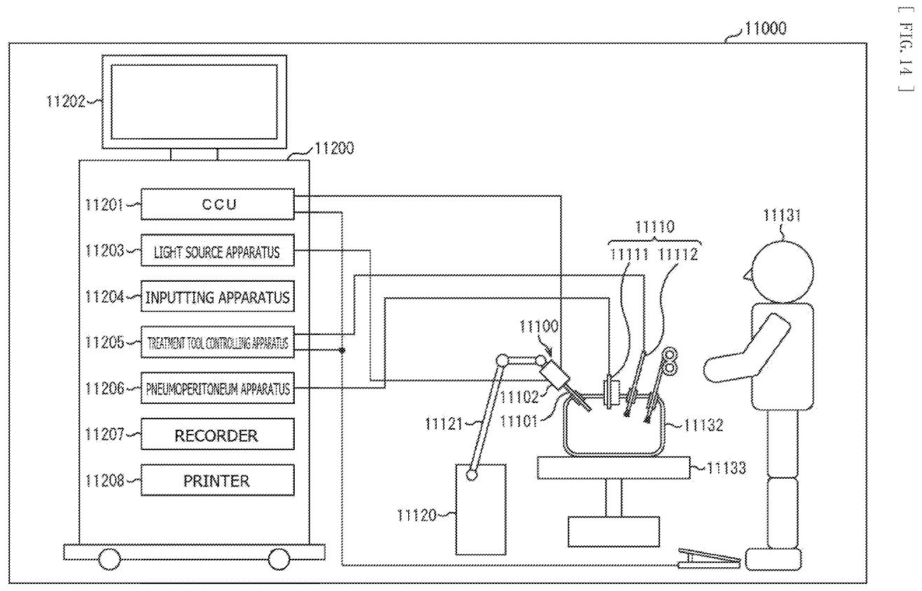

It is to be noted that the present technology is also applicable to a case where an electron is read out from the lower electrode 11 side as signal charge, for example, like an imaging element 1B (see, for example, FIG. 12A) described below. In that case, for example, as illustrated in FIG. 3, the n buffer layer 14 (hole block layer) is disposed on the lower electrode 11 side and the p buffer layer 12 (electron block layer) is disposed on the upper electrode 15 side. In addition, in a case where the first layer 13A and the second layer 13B have energy levels as described above, the first layer 13A is disposed on the p buffer layer 12 side and the second layer 13B is disposed on the n buffer layer 14 side. In other words, the first layer 13A is disposed on the upper electrode 15 side and the second layer 13B is disposed on the lower electrode 11 side.

It is to be noted that there may be provided other layers between the photoelectric conversion layer 13 and the lower electrode 11 and between the photoelectric conversion layer 13 and the upper electrode 15. For example, as illustrated in FIG. 3, there may be provided a work function adjustment layer 16 and an electron injection layer 17 between the p buffer layer 12 and the upper electrode 15. Further, although not illustrated, there may be provided an underlying layer or a hole transport layer between the lower electrode 11 and then buffer layer 14.

### 1-2. Configuration of Imaging Element

FIG. 4 illustrates an example of an overall configuration of an imaging element (imaging element 1) according to an embodiment of the present disclosure. As described above, the imaging element 1 is, for example, a CMOS image sensor. The imaging element 1 takes in incident light (image light) from a subject through an optical lens system (not illustrated). The imaging element 1 converts the amount of incident light formed on the imaging surface as an image into electric signals in units of pixels and outputs the electric signals as pixel signals. The imaging element 1 includes a pixel portion 100 serving as an imaging area on a semiconductor substrate 30. In addition, the imaging element 1 includes, for example, a vertical drive circuit 111, a column signal processing circuit 112, a horizontal drive circuit 113, an output circuit 114, a control circuit 115, and an input/output terminal 116 in a peripheral region (peripheral portion) of this pixel portion 100.

The pixel portion 100 includes, for example, the plurality of unit pixels P that is two-dimensionally disposed in a matrix. These unit pixels P are provided, for example, with a pixel drive line Lread (specifically, a row selection line and a reset control line) for each of the pixel rows and provided with a vertical signal line Lsig for each of the pixel columns. The pixel drive line Lread is for transmitting drive signals for reading out signals from the unit pixels P. One end of the pixel drive line Lread is coupled to the output terminal of the vertical drive circuit 111 corresponding to each of the rows.

The vertical drive circuit 111 includes a shift register, an address decoder, and the like. The vertical drive circuit 111 is a pixel driver that drives the respective unit pixels P of the pixel portion 100, for example, in units of rows. The signals outputted from the respective unit pixels P in the pixel rows selectively scanned by the vertical drive circuit 111 are supplied to the column signal processing circuits 112 through the respective vertical signal lines Lsig. Each of the column signal processing circuits 112 includes an amplifier, a horizontal selection switch, and the like that are provided for each of the vertical signal lines Lsig.

The horizontal drive circuit 113 includes a shift register, an address decoder, and the like. The horizontal drive circuit 113 drives the respective horizontal selection switches of the column signal processing circuits 112 in order while scanning the horizontal selection switches. This selective scanning by the horizontal drive circuit 113 outputs the signals of the respective unit pixels P transmitted through the respective vertical signal lines Lsig to a horizontal signal line 121 in order and transmits the signals to the outside of the semiconductor substrate 30 through the horizontal signal line 121.

The output circuit 114 performs signal processing on signals sequentially supplied from the respective column signal processing circuits 112 through the horizontal signal line 121 and outputs the signals. The output circuit 114 performs, for example, only buffering in some cases and performs black level adjustment, column variation correction, various kinds of digital signal processing, and the like in other cases.

The circuit portions including the vertical drive circuit 111, the column signal processing circuit 112, the horizontal drive circuit 113, the horizontal signal line 121, and the output circuit 114 may be formed directly on the semiconductor substrate 30 or may be provided in external control IC. In addition, those circuit portions may be formed in another substrate coupled by a cable or the like.

The control circuit 115 receives a clock supplied from the outside of the semiconductor substrate 30, data for an instruction about an operation mode, and the like and also outputs data such as internal information of the imaging element 1. The control circuit 115 further includes a timing generator that generates a variety of timing signals and controls the driving of peripheral circuits such as the vertical drive circuit 111, the column signal processing circuit 112, and the horizontal drive circuit 113 on the basis of the variety of timing signals generated by the timing generator.

The input/output terminal 116 exchanges signals with the outside.

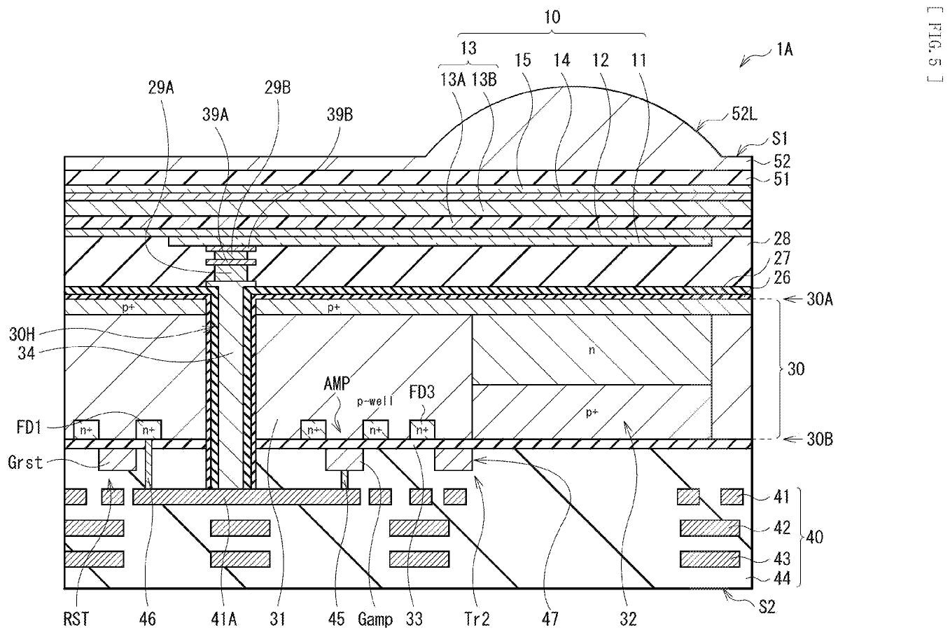

FIG. 5 schematically illustrates an example (imaging element 1A) of a cross-sectional configuration of each of the unit pixels P in the imaging element 1 illustrated in FIG. 4. The imaging element 1A is an imaging element of a so-called vertical spectral type in which one organic photoelectric conversion section and one inorganic photoelectric conversion section 32 are stacked in each of the plurality of unit pixels P in the vertical direction (e.g., Z axis direction). The plurality of unit pixels P is two-dimensionally disposed in the pixel portion 100 in a matrix. The one organic photoelectric conversion section includes the photoelectric converter 10 described above.

It is to be noted that “+ (plus)” attached to “p” and “n” indicates a high concentration of p-type or n-type impurities in the drawings.

The inorganic photoelectric conversion section 32 includes, for example, a photodiode PD that is formed to be buried in the semiconductor substrate 30. The semiconductor substrate 30 has a first surface 30A (back surface) and a second surface 30B (front surface) that are opposed to each other. The organic photoelectric conversion section is provided closer to a light incidence side S1 than the inorganic photoelectric conversion section 32. Specifically, the organic photoelectric conversion section is provided on the first surface 30A side of the semiconductor substrate 30. The organic photoelectric conversion section is the photoelectric converter 10 described above. The p buffer layer 12, the photoelectric conversion layer 13 including the first layer 13A and the second layer 13B, and the n buffer layer 14 are stacked in this order from the lower electrode 11 side between the lower electrode 11 and the upper electrode 15 disposed to be opposed to each other. The organic photoelectric conversion section (photoelectric converter 10) and the inorganic photoelectric conversion section 32 detect pieces of light in wavelength regions different from each other and perform photoelectric conversion. Specifically, the organic photoelectric conversion section detects a portion or all of the wavelengths in the visible light region (e.g., wavelengths of 400 nm or more and 700 nm or less) and the inorganic photoelectric conversion section 32 detects, for example, a portion or all of the wavelengths in the infrared light region (wavelengths of 880 nm or more and 1040 nm or less).

It is to be noted that FIG. 5 illustrates the back surface (first surface 30A) side of the semiconductor substrate 30 as the light incidence side S1 and the front surface (second surface 30B) side thereof as a wiring layer side S2.

The semiconductor substrate 30 includes, for example, an n-type silicon (Si) substrate and includes a p-well 31 in a predetermined region. The second surface (the front surface of the semiconductor substrate 30) 30B of the p-well 31 is provided, for example, with the variety of floating diffusions (floating diffusion layers) FD (e.g., FD1 and FD2), a variety of transistors Tr (e.g., a transfer transistor Tr2, an amplifier transistor AMP, and a reset transistor RST) included in the respective readout circuits of the inorganic photoelectric conversion section 32 and the organic photoelectric conversion section, and a multilayer wiring layer 40. The multilayer wiring layer 40 has a configuration in which, for example, wiring layer 41, 42, and 43 are stacked in an insulating layer 44. The peripheral portion of the semiconductor substrate 30 is provided with a peripheral circuit (not illustrated) including a logic circuit or the like.

The inorganic photoelectric conversion section 32 includes, for example, a PIN (Positive Intrinsic Negative) type photodiode and has a pn junction in a predetermined region of the semiconductor substrate 30.

Between the first surface 30A of the semiconductor substrate 30 and the lower electrode 11 of the organic photoelectric conversion section, for example, insulating layers 26 and 27 and an interlayer insulating layer 28 are stacked in this order from the semiconductor substrate 30 side. There is provided a protective layer 51 on the upper electrode 15 of the organic photoelectric conversion section. There is provided an on-chip lens layer 52 above the protective layer 51. The on-chip lens layer 52 includes an on-chip lens 52L and also serves as a planarization layer.

There is provided a through hole 30H in the semiconductor substrate 30. The through hole 30H extends between the first surface 30A and the second surface 30B. There is provided a through electrode 34 in the through hole 30H. The insulating layers 26 and 27 extend on the side surface of the through hole 30H. This electrically insulates the through electrode 34 and the semiconductor substrate 30. The organic photoelectric conversion section (photoelectric converter 10) is coupled to a gate Gamp of the amplifier transistor AMP and the floating diffusion FD1 through this through electrode 34. This allows the imaging element 1 to favorably transfer electric charge (holes) generated by the organic photoelectric conversion section on the first surface 30A side of the semiconductor substrate 30 to the second surface 30B side of the semiconductor substrate 30 through the through electrode 34 and have increased characteristics.

The through electrode 34 is provided, for example, for each of the unit pixels P. The through electrode 34 has a function of a connector for the organic photoelectric conversion section (photoelectric converter 10), and the gate Gamp of the amplifier transistor AMP and the floating diffusion FD1. In addition, the through electrode 34 serves as a transmission path for electric charge generated by the organic photoelectric conversion section.

The lower end of the through electrode 34 is coupled, for example, to a coupling section 41A in the wiring layer 41 and the coupling section 41A and the gate Gamp of the amplifier transistor AMP are coupled through a lower first contact 45. The coupling section 41A and the floating diffusion FD1 are coupled to the lower electrode 11 through a lower second contact 46. It is to be noted that FIG. 5 illustrates the through electrode 34 having a columnar shape, but this is not limitative. The through electrode 34 may have, for example, a tapered shape.

As illustrated in FIG. 5, a reset gate Grst of the reset transistor RST is disposed next to the floating diffusion FD1. This allows the reset transistor RST to reset the electric charge accumulated in the floating diffusion FD1.

The insulating layer 26 may be a film having positive fixed electric charge or a film having negative fixed electric charge. Examples of a material of the film having negative fixed electric charge include hafnium oxide (HfO₂), aluminum oxide (Al₂O₃), zirconium oxide (ZrO₂), tantalum oxide (Ta₂O₅), titanium oxide (TiO₂), and the like. In addition, as a material other than the materials described, lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, an aluminum oxynitride film, or the like may be used.

The insulating layer 26 may have a configuration in which two or more types of films are stacked. This makes it possible to further increase a function of a hole accumulation layer in a case of a film having, for example, negative fixed electric charge.

A material of the insulating layer 27 is not particularly limited. The insulating layer 27 is formed by using, for example, a silicon oxide film, a TEOS film, a silicon nitride film, a silicon oxynitride film, or the like.

The interlayer insulating layer 28 includes, for example, a single layer film including one of silicon oxide (SiO), silicon nitride (SiN), silicon oxynitride (SiON), or the like or a stacked film including two or more thereof.

The protective layer 51 includes a material having light transmissivity. The protective layer 51 includes, for example, a single layer film including any of silicon oxide, silicon nitride, silicon oxynitride, or the like or a stacked film including two or more thereof. This protective layer 51 has, for example, a thickness of 100 nm to 30000 nm.

The on-chip lens layer 52 is formed on the protective layer 51 to cover the whole surface thereof. The plurality of on-chip lenses (microlenses) 52L is provided on the surface of the on-chip lens layer 52. The on-chip lenses 52L each condense light coming from the above on the respective light receiving surfaces of the organic photoelectric conversion section (photoelectric converter 10) and the inorganic photoelectric conversion section 32. In the present embodiment, the multilayer wiring layer 40 is formed on the second surface 30B side of the semiconductor substrate 30. This allows the light receiving surface of the organic photoelectric conversion section (photoelectric converter 10) and the light receiving surface of the inorganic photoelectric conversion section 32 to be disposed close to each other, thus making it possible to reduce sensitivity variations between the respective colors generated depending on the F-number of the on-chip lens 52L.

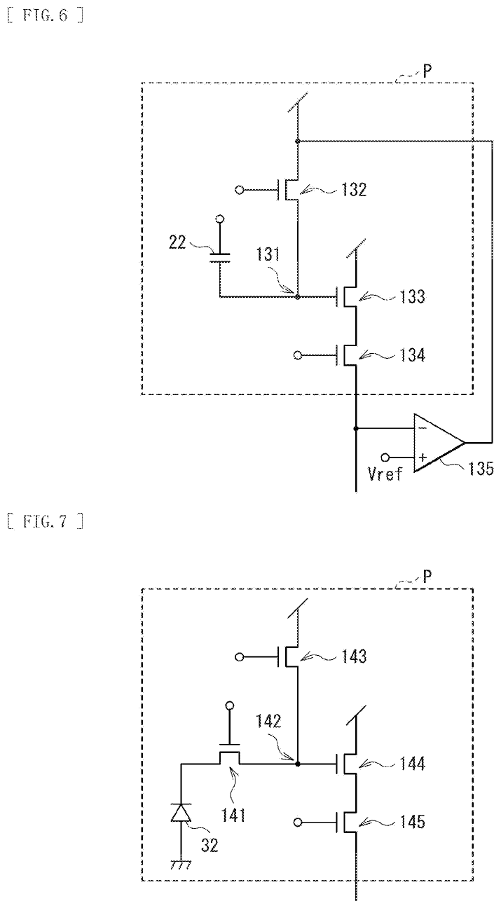

FIGS. 6 and 7 illustrate examples of readout circuits of the organic photoelectric conversion section (FIG. 6) and the inorganic photoelectric conversion section 32 (FIG. 7) included in the unit pixel P of the imaging element 1 illustrated in FIG. 4.

### (Readout Circuit of Organic Photoelectric Conversion Section)

The readout circuit of the organic photoelectric conversion section includes, for example, a floating diffusion (FD) 131, a reset transistor RST 132, an amplifier transistor AMP 133, and a selection transistor SEL 134. Further, the unit pixel P is provided with a feedback amplifier FBAMP 135 for feeding back a readout signal to a reset signal for the readout circuit.

The FD 131 is coupled between the organic photoelectric conversion section and the amplifier transistor AMP 133. The FD 131 performs electric charge voltage conversion to convert signal charge generated by the organic photoelectric conversion section into a voltage signal and makes an output to the amplifier transistor AMP 133.

The gate electrode of the amplifier transistor AMP 133 is coupled to the FD 131 and the drain electrode thereof is coupled to the power supply section. The amplifier transistor AMP 133 serves as an input section of a readout circuit of a voltage signal held in the FD 131. In other words, the amplifier transistor AMP 133 serves as an input section of a so-called source follower circuit. In other words, the source electrode of the amplifier transistor AMP 133 is coupled to the vertical signal line Lsig through the selection transistor SEL 134. This configures a constant current source and the source follower circuit. The constant current source is coupled to one end of the vertical signal line Lsig.

The selection transistor SEL 134 is coupled between the source electrode of the amplifier transistor AMP 133 and the vertical signal line Lsig. A drive signal SELsig is applied to the gate electrode of the selection transistor SEL 134. In a case where this drive signal SELsig enters the active state, the selection transistor 134 enters the conduction state and the unit pixel P enters the selected state. This causes a readout signal (pixel signal) outputted from the amplifier transistor AMP 133 to be outputted to the pixel drive line Lread through the selection transistor SEL 134.

The reset transistor RST 132 is coupled between the FD 131 and the power supply section. A drive signal RSTsig is applied to the gate electrode of the reset transistor RST 132. In a case where this drive signal RSTsig enters the active state, the reset gate of the reset transistor RST 132 enters the conduction state and the FD 131 is supplied with a reset signal for resetting the FD 131.

The feedback amplifier FBAMP 135 has one (−) of the input terminals coupled to the vertical signal line Lsig coupled to the selection transistor SEL 134 and has the other input terminal (+) coupled to a reference voltage section (Vref). The output terminal of the feedback amplifier FBAMP 135 is coupled between the reset transistor RST 132 and the power supply section. The feedback amplifier FBAMP 135 feeds back a readout signal (pixel signal) from each of the unit pixels P to a reset signal by the reset transistor RST 132.

Specifically, in a case where the reset transistor RST 132 resets the FD 131, the drive signal RSTsig enters the active state and the reset gate enters the conduction state. In this case, the feedback amplifier FBAMP 135 provides a necessary gain to an output signal of the selection transistor SEL 134 for feedback to cancel noise of the input section of the amplifier transistor AMP 133.

### (Readout Circuit of Inorganic Photoelectric Conversion Section)

The readout circuit of the inorganic photoelectric conversion section 32 includes, for example, a transfer transistor TG 141, FD 142, a reset transistor RST 143, an amplifier transistor AMP 144, and a selection transistor SEL 145.

The transfer transistor TG 141 is coupled between the inorganic photoelectric conversion section 32 and the FD 142. A drive signal TGsig is applied to the gate electrode of the transfer transistor TG 141. In a case where this drive signal TGsig enters the active state, the transfer gate of the transfer transistor TG 141 enters the conduction state and the signal charge accumulated in the inorganic photoelectric conversion section 32 is transferred to the FD 142 through the transfer transistor TG 141.

The FD 142 is coupled between the transfer transistor TG 141 and the amplifier transistor AMP 144. The FD 142 performs electric charge voltage conversion to convert signal charge transferred by the transfer transistor TG 141 into a voltage signal and makes an output to the amplifier transistor AMP 144.

The reset transistor RST 133 is coupled between the FD 142 and the power supply section. The drive signal RSTsig is applied to the gate electrode of the reset transistor RST 133. In a case where this drive signal RSTsig enters the active state, the reset gate of the reset transistor RST 133 enters the conduction state and the potential of the FD 142 is reset to the level of the power supply section.

The gate electrode of the amplifier transistor AMP 144 is coupled to the FD 142 and the drain electrode thereof is coupled to the power supply section. The amplifier transistor AMP 144 serves as an input section of a readout circuit of a voltage signal held in the FD 142. In other words, the amplifier transistor AMP 144 serves as an input section of a so-called source follower circuit. In other words, the source electrode of the amplifier transistor AMP 144 is coupled to the vertical signal line Lsig through the selection transistor SEL 135. This configures the source follower circuit along with a constant current source coupled to one end of the vertical signal line Lsig.

The selection transistor SEL 135 is coupled between the source electrode of the amplifier transistor AMP 144 and the vertical signal line Lsig. The drive signal SELsig is applied to the gate electrode of the selection transistor SEL 135. In a case where this drive signal SELsig enters the active state, the selection transistor SEL 135 enters the conduction state and the unit pixel P enters the selected state. This causes a readout signal (pixel signal) outputted from the amplifier transistor AMP 144 to be outputted to the vertical signal line Lsig through the selection transistor SEL 135.

### 1-3. Workings and Effects

The photoelectric converter 10 according to the present embodiment is provided with the photoelectric conversion layer 13 between the lower electrode 11 and the upper electrode 15. In the photoelectric conversion layer 13, the first layer 13A and the second layer 13B are directly stacked in this order. The first layer 13A and the second layer 13B have light absorption waveforms different from each other. This makes it possible to reduce the thickness of the photoelectric conversion layer 13. The following describes this.

As described above, a solid-state imaging element including a photoelectric conversion layer in which two types of light absorbing materials are mixed has been reported as a panchromatic solid-state imaging element having sensitivity to the whole visible light wavelengths. In this solid-state imaging element, a dye corresponding to the red region and the green region and a C60 fullerene corresponding to the blue region are used, for example, as the two types of light absorbing materials.

In a case where the photoelectric conversion layer is formed by using two types of materials in this way, the two types of materials are requested to satisfy three functions: absorbing light; transporting a hole; and transporting an electron. This limits the choices of materials and makes it difficult to adjust the spectral shape, raising an issue about the increased thickness of the photoelectric conversion layer.

In contrast, the photoelectric conversion layer 13 of the photoelectric converter 10 according to the present embodiment is formed by using the two layers of the first layer 13A and the second layer 13B having light absorption waveforms different from each other. These first layer 13A and second layer 13B are formed by using dye materials and electron transport materials. The dye materials have light absorption waveforms different from each other. This makes it easier to adjust the spectral shape while retaining the electric charge mobility as compared with a case where the photoelectric conversion layer is formed by using two types of light absorbing materials as described above. This makes it possible to reduce the thickness of the photoelectric conversion layer 13.

As described above, the photoelectric converter 10 according to the present embodiment and the imaging element 1 including this photoelectric converter 10 are each provided with the photoelectric conversion layer 13 in which the first layer 13A and the second layer 13B are directly stacked that each include dye materials having light absorption waveforms different from each other and an electron transport material. This reduces the photoelectric conversion layer in film thickness. This makes it possible to increase the photoresponsivity and improve the afterimage characteristics.

In addition, in the present embodiment, the material selectivity is increased. It is thus possible to increase the photoelectric conversion efficiency, for example, within the wide wavelength range of the visible light region.

Further, in the present embodiment, out of the first layer 13A and the second layer 13B included in the photoelectric conversion layer 13, the first layer 13A to be provided on the p buffer layer 12 side has a shallower ionization potential than the ionization potential of the second layer 13B. It is possible to achieve the first layer 13A and the second layer 13B having the configurations described above by selecting, as at least one of a dye material, an electron transport material, or a hole transport material included in the first layer 13A, a material having a shallower ionization potential than the ionization potential of a material included in the corresponding second layer 13B. This makes it possible to efficiently transport the hole of an electron-hole pair generated through photoelectric conversion by the second layer 13B to the electrode side disposed with the p buffer layer 12 interposed in between. This makes it possible to further increase the photoresponsivity.

Next, modification examples 1 to 5 of the present disclosure are described. The following assigns the same signs to components similar to those of the embodiment described above and omits descriptions thereof as appropriate.

### 2. MODIFICATION EXAMPLES

### 2-1. Modification Example 1

FIG. 8 schematically illustrates an example of a cross-sectional configuration of a photoelectric converter (photoelectric converter 10A) according to the modification example 1 of the present disclosure. In the photoelectric converter 10A according to the present modification example, the first layer 13A described in the embodiment described above is disposed on the upper electrode 15 side and the second layer 13B is disposed on the lower electrode 11 side. Pieces of light in the wavelength regions corresponding to red (R), green (G), and blue (B) may be absorbed in any order in this way. In the present modification example, it is possible to obtain effects similar to those of the embodiment described above.

### 2-2. Modification Example 2

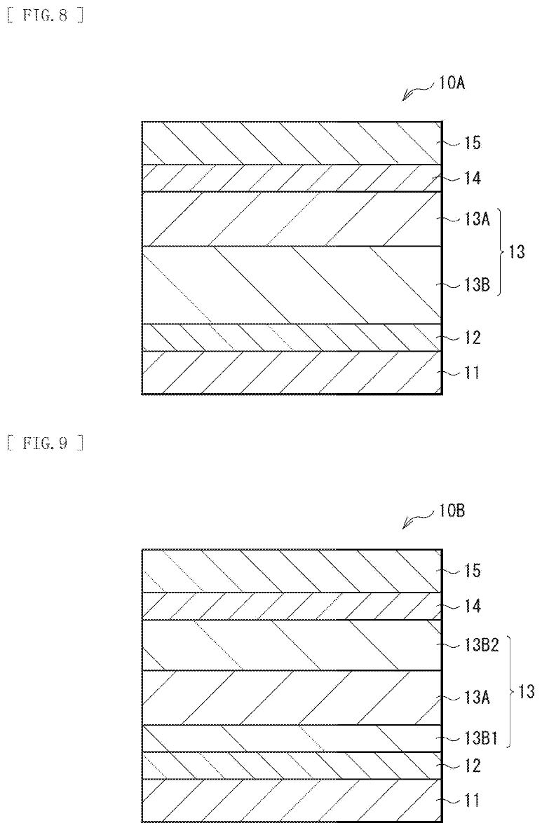

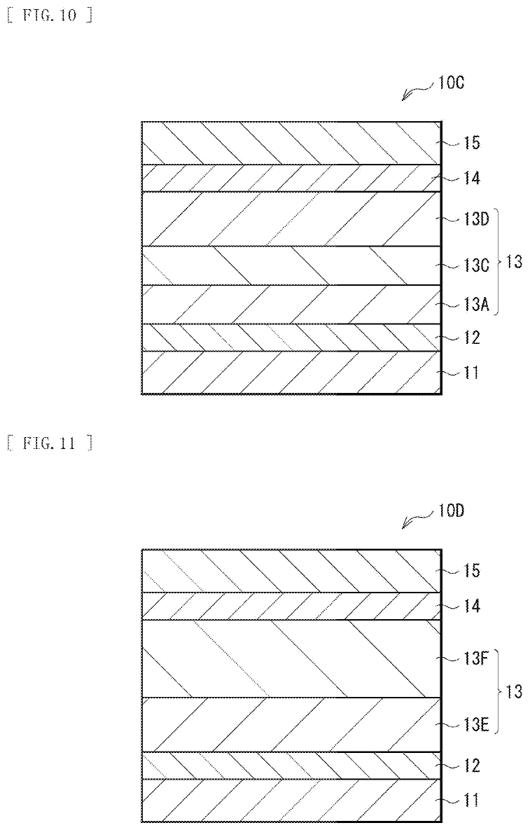

FIG. 9 schematically illustrates an example of a cross-sectional configuration of a photoelectric converter (photoelectric converter 10B) according to the modification example 2 of the present disclosure. In the photoelectric converter 10B according to the present modification example, the second layer 13B that absorbs, for example, pieces of light in the wavelength regions of 500 nm or more and 760 nm or less corresponding to green and red is divided into two layers (layer 13B1 and 13B2) and the first layer 13A that absorbs light in the wavelength region of 400 nm or more and 500 nm or less corresponding to blue is sandwiched in between.

In this way, the photoelectric conversion layer 13 may be provided with a plurality of layers (e.g., the second layer 13B) that absorbs pieces of light in a predetermined wavelength region above and below a layer (e.g., the first layer 13A) that absorbs light in another wavelength region. This causes the photoelectric converter 10B according to the present modification example to attain an effect of further reducing the irradiation wavelength dependency of the photoelectric converter in addition to the effects of the embodiment described above.

### 2-3. Modification Example 3

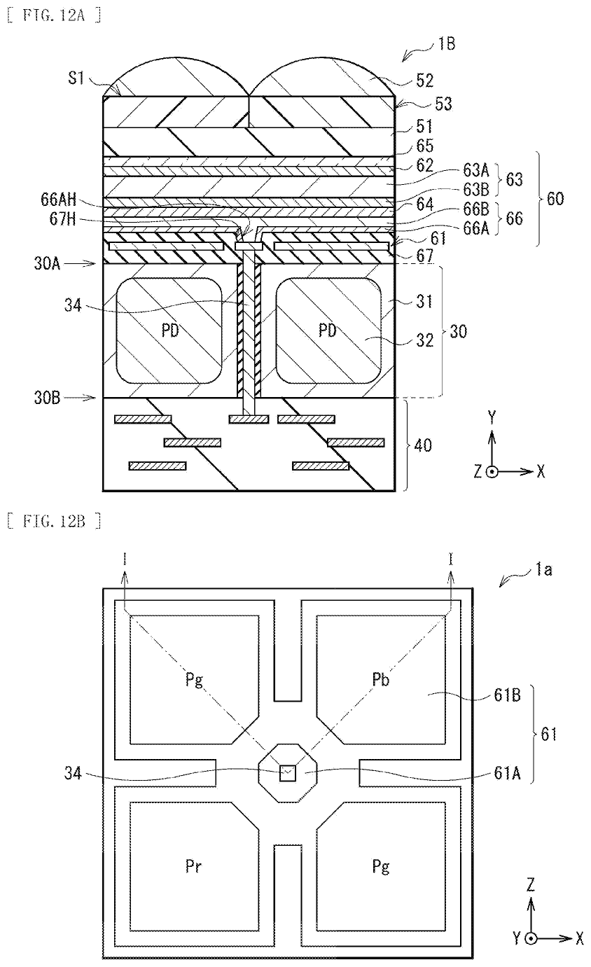

FIG. 10 schematically illustrates an example of a cross-sectional configuration of a photoelectric converter (photoelectric converter 10C) according to the modification example 3 of the present disclosure. The photoelectric converter 10C according to the present modification example includes the photoelectric conversion layer 13 in which the three layers of the first layer 13A, a second layer 13C, and a third layer 13D are directly stacked in order from the lower electrode 11 side. The first layer 13A absorbs light in the wavelength region corresponding, for example, to blue. The second layer 13C absorbs light in the wavelength region corresponding, for example, to green. The third layer 13D absorbs light in the wavelength region corresponding, for example, to red.

In this way, the photoelectric conversion layer 13 is not limited to two layers. Three or more layers having light absorption waveforms different from each other may be stacked. This makes it possible to further increase the material selectivity in addition to the effects of the embodiment described above.

### 2-4. Modification Example 4

FIG. 11 schematically illustrates an example of a cross-sectional configuration of a photoelectric converter (photoelectric converter 10D) according to the modification example 4 of the present disclosure. The photoelectric converter 10D according to the present modification example includes the photoelectric conversion layer 13 in which a first layer 13E and a second layer 13F are stacked. The first layer 13E absorbs, for example, light in the visible light region. The second layer 13F absorbs, for example, light in the near-infrared region (NIR) of 780 nm or more and 2000 nm or less.

In this way, the photoelectric conversion layer 13 is provided with a layer (e.g., the second layer 13F) that absorbs light in a region other than the visible light region. This is stacked on the layer (e.g., the first layer 13E) that absorbs light in the visible light region. This makes it possible to achieve a photoelectric converter having excellent afterimage characteristics and configured to absorb pieces of light corresponding to the visible light region to the near-infrared region and generate an electron-hole pair (exciton).

### 2-5. Modification Example 5

FIG. 12A schematically illustrates a cross-sectional configuration of an imaging element (imaging element 1B) according to the modification example 5 of the present disclosure. FIG. 12B schematically illustrates an example of a planar configuration of the imaging element 1B illustrated in FIG. 12A. FIG. 12A illustrates a cross section taken along the I-I line illustrated in FIG. 12B. The imaging element 1B is a stacked imaging element in which, for example, the inorganic photoelectric conversion section 32 and an organic photoelectric conversion section 60 are stacked. In the pixel portion 100 of the imaging element 1, for example, illustrated in FIG. 4, pixel units 1a are repeatedly disposed as repeating units in an array having the row direction and the column direction. Each of the pixel units 1a includes four pixels disposed, for example, in two rows and two columns, for example, as illustrated in FIG. 12B.

The imaging element 1B according to the present modification is provided with color filters 53 above the organic photoelectric conversion sections 60 (light incidence side Si) for the respective unit pixels P. The respective color filters 53 selectively transmit red light (R), green light (G), and blue light (B). Specifically, in the pixel unit 1a including four pixels disposed in two rows and two columns, two color filters each of which selectively transmits green light (G) are disposed on a diagonal line and color filters that selectively transmit red light (R) and blue light (B) are disposed one by one on the orthogonal diagonal line. The unit pixels (Pr, Pg, and Pb) provided with the respective color filters each detect the corresponding color light, for example, in the organic photoelectric conversion section 60. In other words, the respective pixels (Pr, Pg, and Pb) that detect red light (R), green light (G), and blue light (B) have a Bayer arrangement in the pixel portion 100.

The imaging element 1B according to the present modification example reads out the electron of an electron-hole pair (exciton) generated through photoelectric conversion as signal charge. The organic photoelectric conversion section 60 has a configuration in which, for example, a lower electrode 61, an n buffer layer 62, a photoelectric conversion layer 63, a p buffer layer 64, and an upper electrode 65 are stacked in this order. The lower electrode 61 includes a plurality of electrodes including, for example, a readout electrode 61A and an accumulation electrode 61B. The semiconductor layer 66 including, for example, two layer 66A and 66B is provided between the lower electrode 61 and then buffer layer 62. In the photoelectric conversion layer 63, for example, a first layer 63A and a second layer 63B are directly stacked in this order, for example, as with the photoelectric conversion layer 13 according to the embodiment or the like described above. The lower electrode 61 is buried, for example, in an interlayer insulating layer 67. The interlayer insulating layer 67 has an opening 67H on the readout electrode 61A. The inorganic photoelectric conversion section 32 detects light in a wavelength range different from that of the organic photoelectric conversion section 60.

The lower electrode 61 includes the readout electrode 61A and the accumulation electrode 61B as described above. It is possible to independently apply voltages to the readout electrode 61A and the accumulation electrode 61B. The n buffer layer 62, the photoelectric conversion layer 63, the p buffer layer 64, and the upper electrode 65 respectively have configurations similar to those of the n buffer layer 14, the photoelectric conversion layer 13, the p buffer layer 12, and the upper electrode 15 according to the embodiment or the like described above.

The semiconductor layer 66 is for accumulating electric charge generated by the photoelectric conversion layer 63. The layer 66A is for preventing the electric charge accumulated in the semiconductor layer 66 from being trapped at the interface with the interlayer insulating layer 67 and efficiently transferring the electric charge to the readout electrode 61A. The layer 66B is for preventing electric charge generated by the photoelectric conversion layer 63 from being trapped at the interface with the semiconductor layer 66. The layer 66A is provided with an opening 66AH in the opening 67H on the readout electrode 61A. The readout electrode 61A and the layer 66B are electrically coupled. It is possible to form each of the layer 66A and 66B by using, for example, an oxide semiconductor material.

The interlayer insulating layer 67 is for electrically separating the semiconductor substrate 30 and the organic photoelectric conversion section 60 and electrically separating the accumulation electrode 61B and the semiconductor layer 66. The interlayer insulating layer 67 includes a single layer film including one of silicon oxide (SiOₓ), silicon nitride (SiNₓ), silicon oxynitride (SiON), or the like or a stacked film including two or more thereof.

In the imaging element 1B, pieces of light (red light (R), green light (G), and blue light (B)) in the visible light region among the pieces of light passing through the color filters 53 are absorbed by the organic photoelectric conversion sections 60 of the unit pixels (Pr, Pg, and Pb) provided with the respective color filters. The other light including, for example, light (infrared light (IR)) in the infrared light region (e.g., 700 nm or more and 1000 nm or less) passes through each of the organic photoelectric conversion sections 60. This infrared light (IR) passing through the organic photoelectric conversion section 60 is detected by the inorganic photoelectric conversion section 32 of each of the unit pixels Pr, Pg, and Pb. Each of the unit pixels Pr, Pg, and Pb generates the signal charge corresponding to the infrared light (IR). In other words, the imaging element 1B is configured to concurrently generate both a visible light image and an infrared light image.

### 3. APPLICATION EXAMPLE

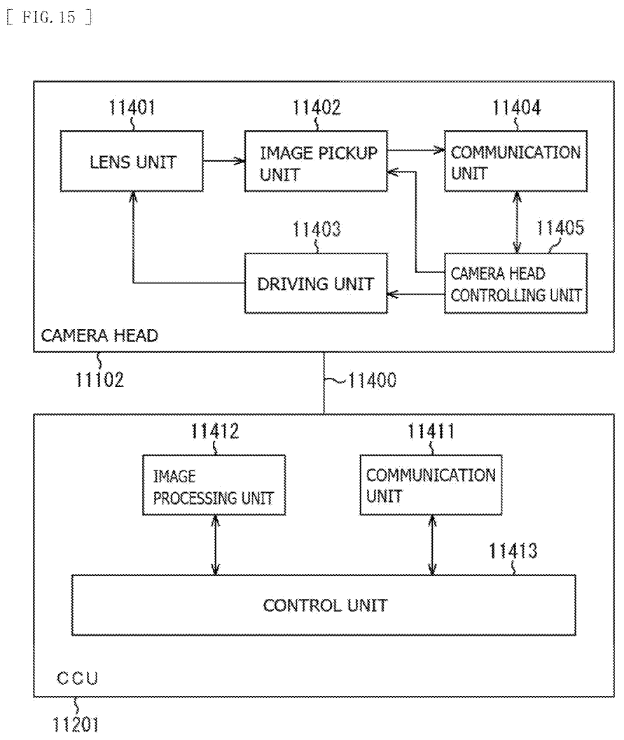

The imaging element 1 or the like described above is applicable, for example, to any type of electronic apparatus (imaging device) having an imaging function. The electronic apparatus (imaging device) includes a camera system such as a digital still camera or a video camera, a mobile phone having the imaging function, and the like. FIG. 13 illustrates a schematic configuration of an electronic apparatus 1000.

The electronic apparatus 1000 includes, for example, a lens group 1001, the imaging element 1, a DSP (Digital Signal Processor) circuit 1002, a frame memory 1003, a display section 1004, a recording section 1005, an operation section 1006, and a power supply section 1007. They are coupled to each other through a bus line 1008.

The lens group 1001 takes in incident light (image light) from a subject and forms am image on the imaging surface of the imaging element 1. The imaging element 1 converts the amount of incident light formed as an image on the imaging surface by the lens group 1001 into electric signals in units of pixels and supplies the DSP circuit 1002 with the electric signals as pixel signals.

The DSP circuit 1002 is a signal processing circuit that processes a signal supplied from the imaging element 1. The DSP circuit 1002 outputs image data that is obtained by processing the signal from the imaging element 1. The frame memory 1003 temporarily holds the image data processed by the DSP circuit 1002 in units of frames.

The display section 1004 includes, for example, a panel-type display device such as a liquid crystal panel or an organic EL (Electro Luminescence) panel and records the image data of a moving image or a still image captured by the imaging element 1 in a recording medium such as a semiconductor memory or a hard disk.

The operation section 1006 outputs an operation signal for a variety of functions of the electronic apparatus 1000 in accordance with an operation by a user. The power supply section 1007 appropriately supplies the DSP circuit 1002, the frame memory 1003, the display section 1004, the recording section 1005, and the operation section 1006 with various kinds of power for operations of these supply targets.

### 4. Practical Application Examples

### (Example of Practical Application to Endoscopic Surgery System)

The technology (the present technology) according to the present disclosure is applicable to a variety of products. For example, the technology according to the present disclosure may be applied to an endoscopic surgery system.

FIG. 14 is a view depicting an example of a schematic configuration of an endoscopic surgery system to which the technology according to an embodiment of the present disclosure (present technology) can be applied.

In FIG. 14, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

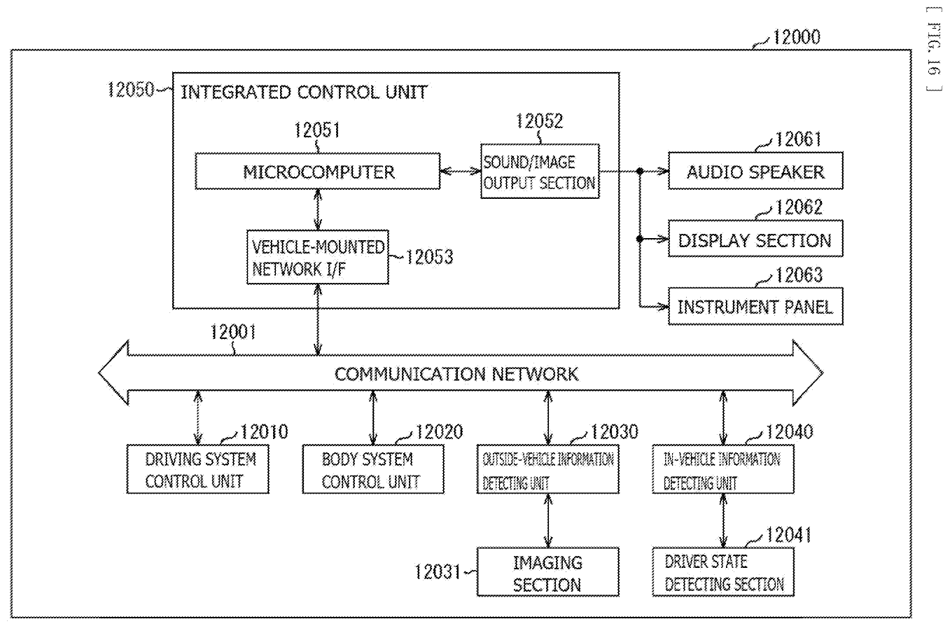

FIG. 15 is a block diagram depicting an example of a functional configuration of the camera head 11102 and the CCU 11201 depicted in FIG. 14.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure may be applied has been described above. The technology according to the present disclosure may be applied to the image pickup unit 11402 among the components described above. The application of the technology according to the present disclosure to the image pickup unit 11402 increases the detection accuracy.

It is to be noted that the endoscopic surgery system has been described here as an example, but the technology according to the present disclosure may be additionally applied, for example, to a microscopic surgery system or the like.

### (Example of Practical Application to Mobile Body)

The technology according to the present disclosure is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

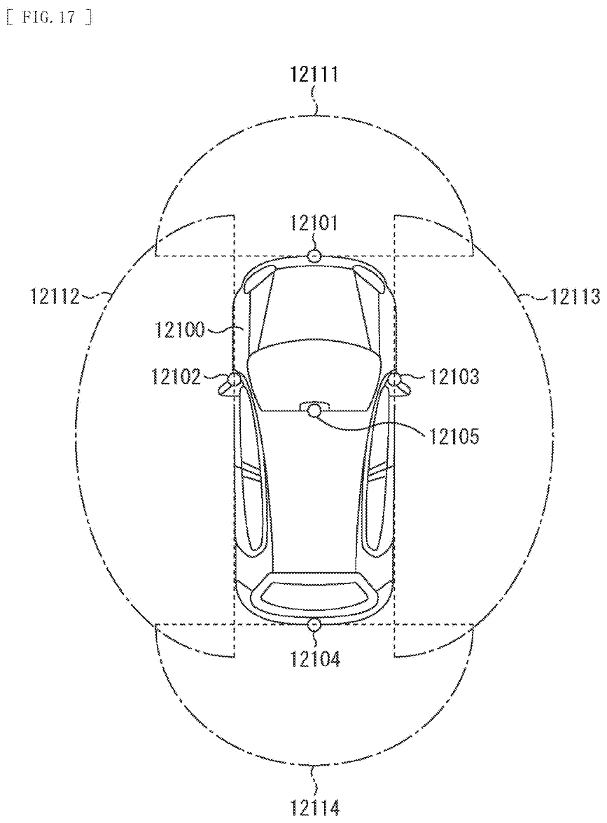

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

FIG. 17 is a diagram depicting an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

### 5. WORKING EXAMPLES

Next, working examples of the present disclosure are described.

### Experimental Example 1

First, a glass substrate provided with an ITO electrode (lower electrode) having a film thickness of 50 nm was cleaned in UV/ozone treatment. Subsequently, the glass substrate was moved to a vacuum evaporation device. A p buffer layer, a photoelectric conversion layer 1 (first layer), a photoelectric conversion layer 2 (second layer), a photoelectric conversion layer 3 (third layer), and an n buffer layer were formed in order on the glass substrate by using a resistive heating method with a substrate holder rotated under a reduced pressure condition of 1×10⁻⁵ Pa or less. In the p buffer layer, the material represented by the following chemical formula (1) was used to have a thickness of 10 nm. In the photoelectric conversion layer 1, the TiOPC represented by the following chemical formula (2) was used as the dye material and a C₆₀ fullerene was used as the electron transport material. The photoelectric conversion layer 1 had a thickness of 100 nm. In the photoelectric conversion layer 2, the BP-BBTBDT represented by the following chemical formula (3) was used as the dye material and a C₆₀ fullerene was used as the electron transport material. The photoelectric conversion layer 2 had a thickness of 100 nm. In the photoelectric conversion layer 3, the TP-rBDT represented by the following chemical formula (4) was used as the hole transport material, the F6SubPc-OPh26F2 represented by the following chemical formula (5) was used as the dye material, and a C₆₀ fullerene was used as the electron transport material. The photoelectric conversion layer 3 had a thickness of 100 nm. In the n buffer layer, the material represented by the following chemical formula (6) was used to have a thickness of 10 nm. Subsequently, an ITO electrode (upper electrode) having a thickness of 50 nm was formed on the n buffer layer. As described above, a photoelectric converter was fabricated that had a photoelectric conversion region of 1 mm×1 mm.

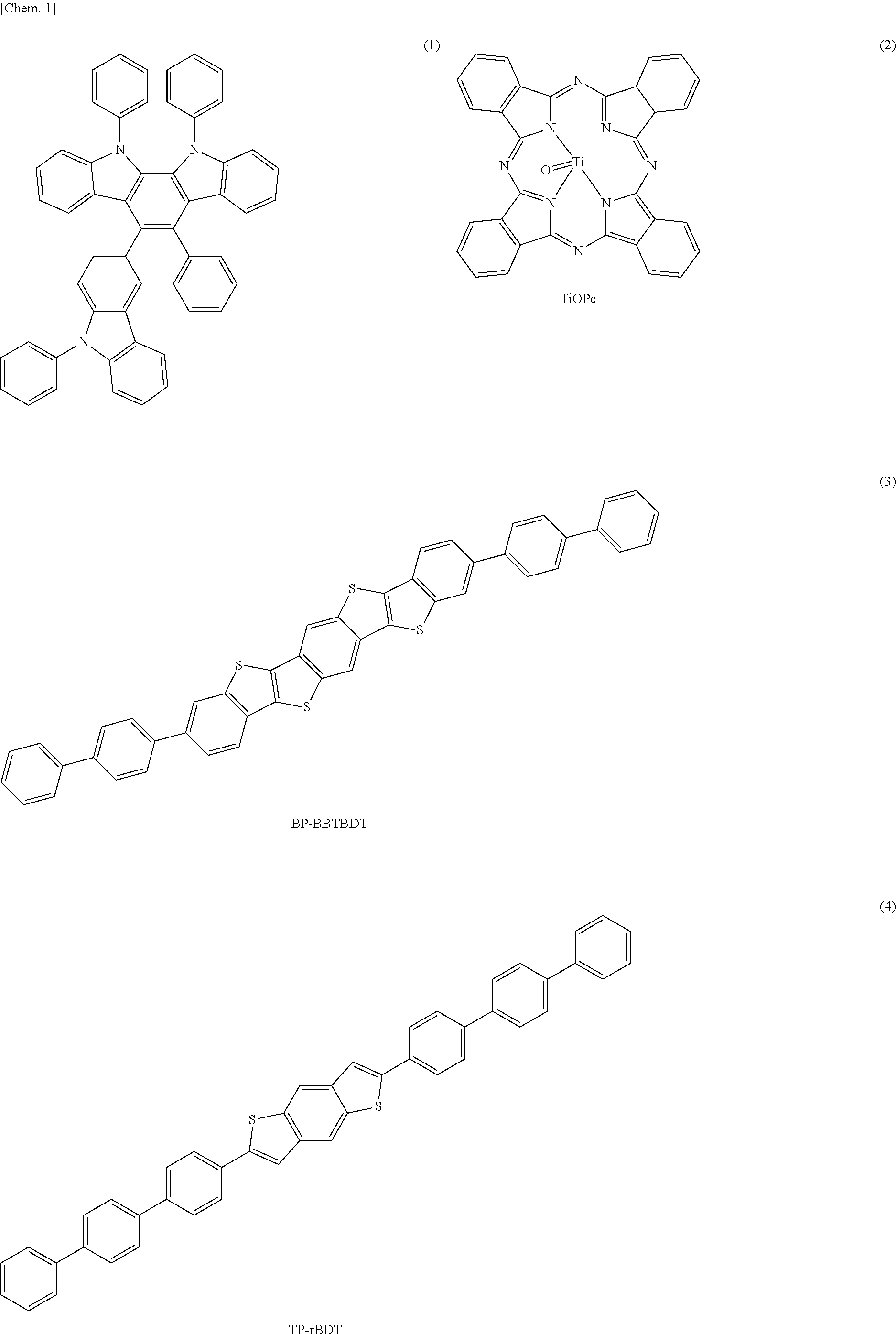

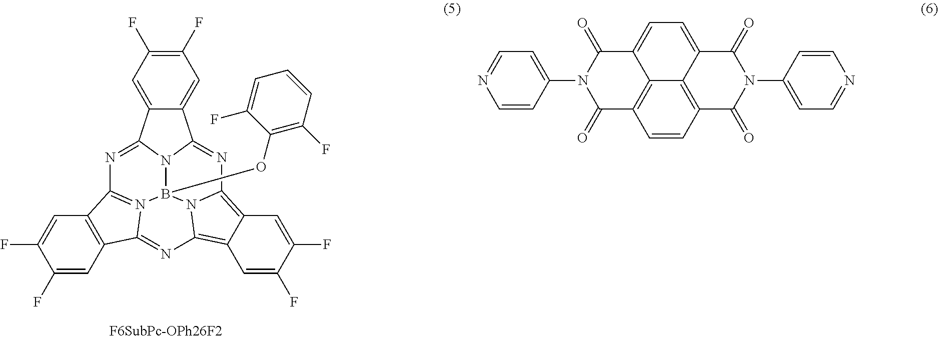

### Experimental Example 2

In an experimental example 2, a photoelectric converter having a configuration similar to that of the experimental example 1 was fabricated except that the photoelectric conversion layer 2 was formed by using the BP-DNTT represented by the following chemical formula (7) as the dye material and using a C₆₀ fullerene as the electron transport material.

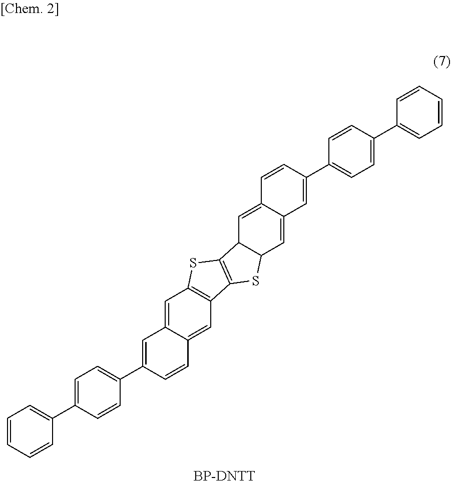

### Experimental Example 3

In an experimental example 3, a photoelectric converter having a configuration similar to that of the experimental example 1 was fabricated except that the photoelectric conversion layer 1 was formed by using the DBP represented by the following chemical formula (8) as the dye material and using a C₆₀ fullerene as the electron transport material.

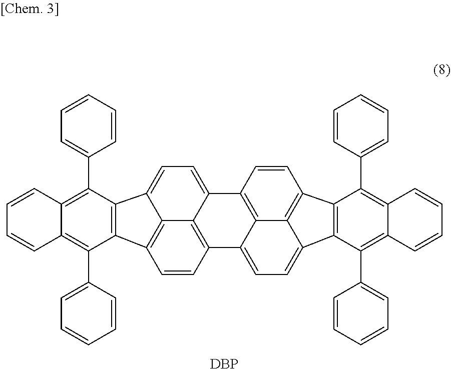 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1 ; "DBP"]

### Experimental Example 4

In an experimental example 4, a photoelectric converter having a configuration similar to that of the experimental example 1 was fabricated except that the photoelectric conversion layer had a two-layer structure of the photoelectric conversion layer 2 and the photoelectric conversion layer 3 according to the experimental example 1.

### Experimental Example 5

In an experimental example 5, a photoelectric converter having a configuration similar to that of the experimental example 1 was fabricated except for a two-layer structure of the photoelectric conversion layer 1 and the photoelectric conversion layer 3 according to the experimental example 1. In the photoelectric conversion layer 1, the TiOPC represented by the chemical formula (2) described above was used as the dye material and a C₇₀ fullerene was used as the electron transport material.

### Experimental Example 6

In an experimental example 6, a photoelectric converter having a configuration similar to that of the experimental example 1 was fabricated except for a two-layer structure of the photoelectric conversion layer 1 and the photoelectric conversion layer 3. In the photoelectric conversion layer 1, the TiOPC represented by the chemical formula (2) described above was used as the dye material and a C₇₀ fullerene was used as the electron transport material. In the photoelectric conversion layer 3, the SubPc-Cl represented by the following chemical formula (9) was used as the dye material and a C₇₀ fullerene was used as the electron transport material.

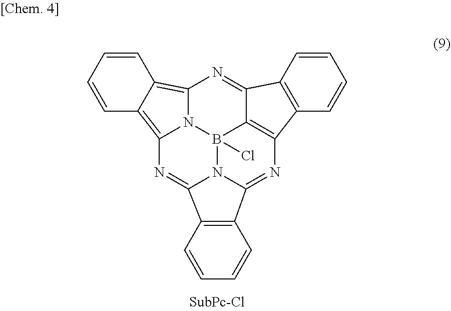

### Experimental Example 7

In an experimental example 7, a photoelectric converter having a configuration similar to that of the experimental example 1 was fabricated except that the photoelectric conversion layer had a single layer structure in which the photoelectric conversion layer included the material having a hole transporting property represented by the following chemical formula (10) and a C₆₀ fullerene having an electron transporting property as dye materials 1 and 2, respectively.

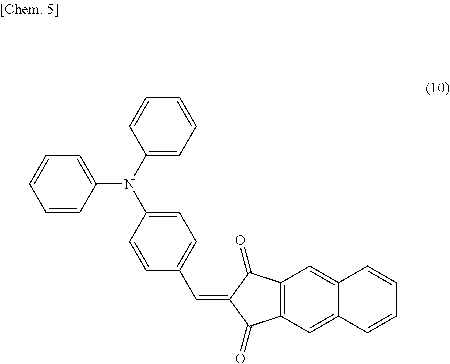 [SMILES: O=C1C(=Cc2ccc(N(c3ccccc3)c3ccccc3)cc2)C(=O)c2cc3ccccc3cc21]

### Experimental Example 8

In an experimental example 8, a photoelectric converter having a configuration similar to that of the experimental example 1 was fabricated except that the photoelectric conversion layer 1 was formed by using the compound represented by the following chemical formula (11) as the dye material and using a C₆₀ fullerene as the electron transport material, the photoelectric conversion layer 2 was formed by using the compound represented by the following chemical formula (12) as the hole transport material, using the F6SubPc-OPh26F2 represented by the chemical formula (5) described above as the dye material, and using a C₆₀ fullerene as the electron transport material, and the photoelectric conversion layer 3 was formed by using the compound represented by the following chemical formula (12) as the hole transport material, using the F12SubPc-OPh26F2 represented by the following chemical formula (13) as the dye material, and using a C₆₀ fullerene as the electron transport material.

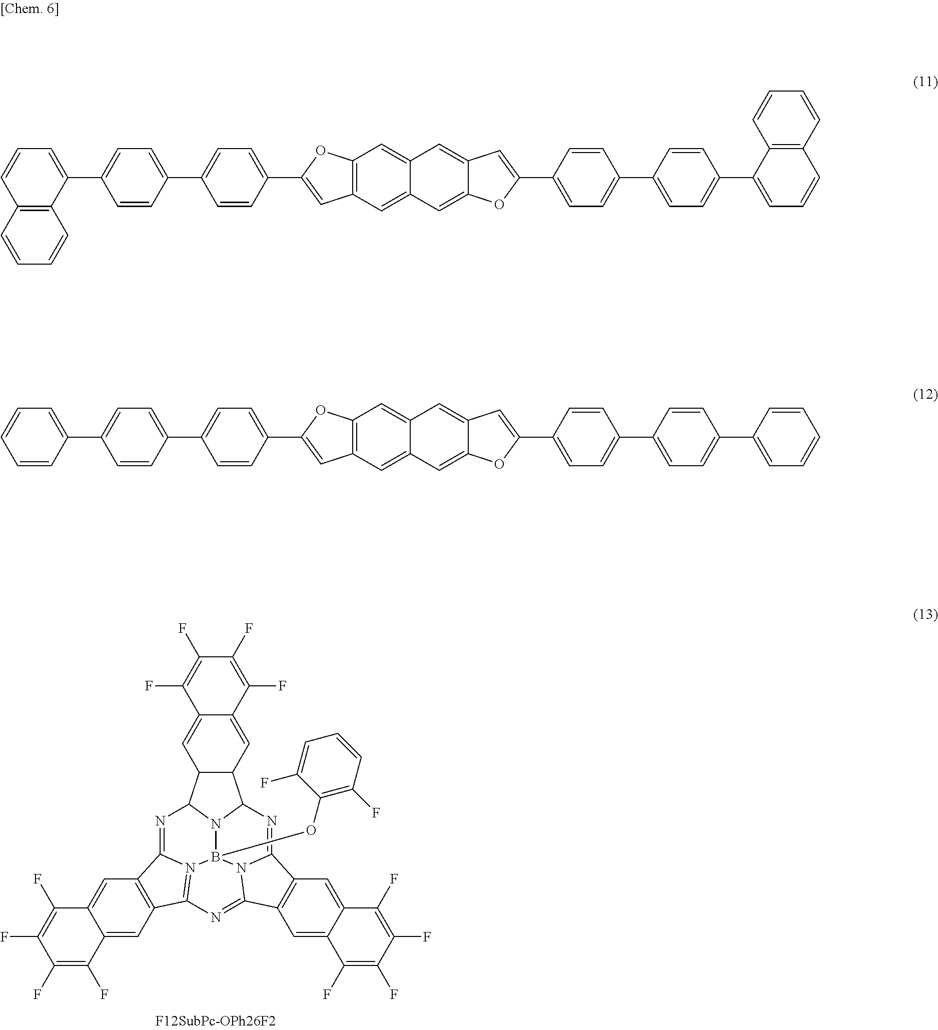

### Experimental Example 9

In an experimental example 9, a photoelectric converter having a configuration similar to that of the experimental example 1 was fabricated except that the photoelectric conversion layer 1 was omitted and a two-layer structure was used of the photoelectric conversion layer 2 and the photoelectric conversion layer 3. In the photoelectric conversion layer 2, the TiOPC represented by the following chemical formula (2) was used as the dye material and a C₆₀ fullerene was used as the electron transport material. In the photoelectric conversion layer 3, the SubPc-Cl represented by the following chemical formula (9) was used as the dye material and a C₆₀ fullerene was used as the electron transport material.

### Experimental Example 10

In an experimental example 10, a photoelectric converter having a configuration similar to that of the experimental example 9 was fabricated except that the photoelectric conversion layer 2 and the photoelectric conversion layer 3 according to the experimental example 9 were conversely formed.

External quantum efficiency (EQE) and photoresponsivity were measured for the experimental examples 1 to 10.

The external quantum efficiency was evaluated by using a semiconductor parameter analyzer. Specifically, the external photoelectric conversion efficiency was calculated from a light current value and a dark current value in a case where the amount of light (LED light having a wavelength of 560 nm) with which the photoelectric converter was irradiated from the light source through the filter was set at 1.62 μW/cm² and the bias voltage to be applied between the electrodes was set to −2.6 V.

The photoresponsivity was evaluated by measuring the speed at which the light current value observed at the time of light irradiation fell after the light irradiation was stopped by using the semiconductor parameter analyzer. Specifically, the amount of light (LED light having a wavelength of 560 nm) with which the photoelectric converter was irradiated from the light source through the filter was set at 1.62 μW/cm2 and the bias voltage to be applied between the electrodes was set to −2.6 V. After a steady current was observed in this state, the light irradiation was stopped and the current attenuation was observed. Subsequently, the area surrounded by a current-time curve and the dark current was set as 100% and the time elapsed before the area corresponded to 3% was considered as an index of the photoresponsivity. All of these evaluations were made at the room temperature.

Table 1 tabulates the configurations of the photoelectric conversion layers according to the experimental examples 1 to 10 and the measurement results of the EQE and the photoresponsivity. Table 2 tabulates the ionization potentials of the dye materials used for the respective photoelectric conversion layers according to the experimental examples 1 to 10. It is to be noted that the values of the experimental examples 1 to 6 and 8 to 10 for EQE and photoresponsivity are relative values obtained in a case where the experimental example 7 was used as a reference (1). In Table 1, a C₆₀ fullerene and a C₇₀ fullerene are respectively represented as C60 and C70.

TABLE 1

| | photoelectric | Photoelectric | photoelectric | | standardized |
|---|---|---|---|---|---|
| | conversion | conversion | conversion | standardized | photoresponsivity |
| | layer 1 | layer 2 | layer 3 | [symbol] | [symbol] |
| experimental example 1 | [symbol] | [symbol] | [symbol] | [symbol] | [symbol] |
| experimental example 2 | [symbol] | [symbol] | [symbol] | [symbol] | [symbol] |
| experimental example 3 | [symbol] | [symbol] | [symbol] | [symbol] | [symbol] |
| experimental example 4 | [symbol] | [symbol] | [symbol] | [symbol] | [symbol] |
| experimental example 5 | [symbol] | [symbol] | [symbol] | [symbol] | [symbol] |
| experimental example 6 | [symbol] | [symbol] | [symbol] | [symbol] | [symbol] |
| experimental example 7 | [symbol] | [symbol] | [symbol] | [symbol] | [symbol] |
| experimental example 8 | [symbol] | [symbol] | [symbol] | [symbol] | [symbol] |
| experimental example 9 | [symbol] | [symbol] | [symbol] | [symbol] | [symbol] |
| experimental example 10 | [symbol] | [symbol] | [symbol] | [symbol] | [symbol] |

[symbol]

indicates data missing or illegible when filed

TABLE 2

| | ionization potentials of dye materials | | |
|---|---|---|---|
| | photoelectric | photoelectric | photoelectric |
| | conversion | conversion | conversion |
| | layer 1 | layer 2 | layer 3 |
| experimental example 1 | 5.7 eV | 5.7 eV | 6.2 eV |
| experimental example 2 | 5.7 eV | 5.7 eV | 6.2 eV |
| experimental example 3 | 5.5 eV | 5.7 eV | 6.2 eV |
| experimental example 4 | — | 5.7 eV | 6.2 eV |
| experimental example 5 | 5.7 eV | — | 6.2 eV |
| experimental example 6 | 5.7 eV | — | 5.7 eV |
| experimental example 7 | 5.6 eV | — | — |
| experimental example 8 | 5.6 eV | 6.2 eV | 6.4 eV |
| experimental example 9 | — | 5.7 eV | 6.0 eV |
| experimental example 10 | — | 6.0 eV | 5.7 eV |

Table 1 indicates that the experimental examples 1 to 6 and 8 to 10 each including a photoelectric conversion layer in which a plurality of layers is stacked in which dye materials having light absorption waveforms different from each other are used each have higher EQE and faster photoresponsivity than those of the experimental example 7 including a photoelectric conversion layer having a single layer structure in which two types of dye materials are mixed. In other words, it was found that providing a photoelectric conversion layer in which a plurality of layers each including dye materials having light absorption waveforms different from each other and a carrier transport material was stacked made it possible to increase the photoresponsivity and improve the afterimage characteristics. In addition, it was found possible to increase the photoelectric conversion efficiency as compared with a case where a photoelectric conversion layer was formed by mixing two types of dye materials.

Further, results of the experimental examples 9 and 10 in which dye materials used for the photoelectric conversion layer 2 and the photoelectric conversion layer 3 are exchanged indicate that a photoelectric conversion layer to be provided on the p buffer layer side includes a dye material having a shallower ionization potential than that of a dye material to be used for another photoelectric conversion layer, thereby making it possible to further increase the EQE and the photoresponsivity.

Although the description has been given with reference to the embodiment, the modification examples 1 to 5, the working examples, the application example, and the practical application examples, the contents of the present disclosure are not limited to the embodiment or the like described above. The present disclosure may be modified in a variety of ways. For example, the imaging element 1A illustrated in FIG. 5 may be provided with a color filter above (light incidence side S1) the organic photoelectric conversion section (photoelectric converter 10). The color filter selectively transmits light having a portion of the wavelengths in the visible light region. This allows the organic photoelectric conversion section to detect light having a portion of the wavelengths in the visible light region.

In addition, the number of organic photoelectric conversion sections and inorganic photoelectric conversion sections and the ratio between organic photoelectric conversion sections and inorganic photoelectric conversion sections are not limited. In addition, a structure is not limited to the structure in which the organic photoelectric conversion section and the inorganic photoelectric conversion section are stacked in the vertical direction, but the organic photoelectric conversion section and the inorganic photoelectric conversion section may be placed side by side along a substrate surface.

Further, in the embodiment or the like described above, the configuration of the back-illuminated imaging element has been described, but the contents of the present disclosure are also applicable to a front-illuminated imaging element. Further, the photoelectric converter according to the present disclosure does not have to include all of the respective components described in the embodiment described above. Meanwhile, the photoelectric converter according to the present disclosure may include another layer.

It is to be noted that the effects described herein are merely examples, but are not limitative. In addition, there may be other effects.

It is to be noted that the present disclosure may also have configurations as follows. According to the present technology having the following configurations, the first photoelectric conversion layer and the second photoelectric conversion layer are provided. The first photoelectric conversion layer and the second photoelectric conversion layer are stacked between the first electrode and the second electrode. The first photoelectric conversion layer includes the first dye material and the first carrier transport material. The second photoelectric conversion layer includes the second dye material and the second carrier transport material. The second dye material has the light absorption waveform different from that of the first dye material. This makes it possible to reduce the thickness of the photoelectric conversion layer and increase the afterimage characteristics.
(1)

A photoelectric converter including:

a first electrode;

a second electrode that is disposed to be opposed to the first electrode;

a first photoelectric conversion layer that is provided between the first electrode and the second electrode, the first photoelectric conversion layer including a first dye material and a first carrier transport material;

a second photoelectric conversion layer that is stacked on the second electrode side of the first photoelectric conversion layer between the first electrode and the second electrode, the second photoelectric conversion layer including a second dye material and a second carrier transport material, the second dye material having a light absorption waveform different from a light absorption waveform of the first dye material;

a first buffer layer having a first electrical conduction type, the first buffer layer being provided between the first electrode and the first photoelectric conversion layer; and

a second buffer layer having a second electrical conduction type different from the first electrical conduction type, the second buffer layer being provided between the second electrode and the second photoelectric conversion layer.
(2)

The photoelectric converter according to (1), in which the first photoelectric conversion layer and the second photoelectric conversion layer are directly stacked.
(3)

The photoelectric converter according to (1) or (2), in which the first photoelectric conversion layer and the second photoelectric conversion layer each have an ionization potential of 6 eV or less.
(4)

The photoelectric converter according to (3), in which the ionization potentials of the first photoelectric conversion layer and the second photoelectric conversion layer have a difference of 0.2 eV or less.
(5)

The photoelectric converter according to (4), in which

the first buffer layer includes a p-type buffer layer, and

the ionization potential of the first photoelectric conversion layer is less than the ionization potential of the second photoelectric conversion layer.
(6)

The photoelectric converter according to (4) or (5), in which electron affinity of the first photoelectric conversion layer and electron affinity of the second photoelectric conversion layer have a difference of 0.2 eV or less.
(7)

The photoelectric converter according to any one of (1) to (6), in which

the first buffer layer includes a p-type buffer layer, and

the first photoelectric conversion layer has a shallower ionization potential than an ionization potential of the second photoelectric conversion layer.
(8)

The photoelectric converter according to any one of (1) to (6), in which the first dye material and the second dye material have ionization potentials that are substantially same as each other.
(9)

The photoelectric converter according to any one of (1) to (6), in which

the first buffer layer includes a p-type buffer layer, and

the first dye material has a shallower ionization potential than an ionization potential of the second dye material.
(10)

The photoelectric converter according to any one of (1) to (9), in which the first carrier transport material and the second carrier transport material include same materials.
(11)

The photoelectric converter according to any one of (1) to (10), in which the first carrier transport material and the second carrier transport material each include an electron transport material.
(12)

The photoelectric converter according to any one of (1) to (11), in which the first photoelectric conversion layer includes a first hole transport material and a first electron transport material as the first carrier transport materials.
(13)

The photoelectric converter according to any one of (1) to (12), in which the second photoelectric conversion layer includes a second hole transport material and a second electron transport material as the second carrier transport materials.
(14)

The photoelectric converter according to any one of (1) to (13), in which

the first photoelectric conversion layer includes a first hole transport material and a first electron transport material as the first carrier transport materials,

the second photoelectric conversion layer includes a second hole transport material and a second electron transport material as the second carrier transport materials, and

the first hole transport material and the second hole transport material have ionization potentials that are substantially same as each other.
(15)

The photoelectric converter according to (14), in which

the first buffer layer includes a p-type buffer layer, and

the first hole transport material has a shallower ionization potential than an ionization potential of the second hole transport material.
(16)

The photoelectric converter according to (14) or (15), in which the first hole transport material and the second hole transport material include same materials.
(17)

The photoelectric converter according to any one of (14) to (16), in which the first electron transport material and the second electron transport material have LUMO levels that are substantially same as each other.
(18)

The photoelectric converter according to any one of (14) to (17), in which

the first buffer layer includes a p-type buffer layer, and

the first electron transport material has a shallower LUMO level than a LUMO level of the second electron transport material.
(19)

The photoelectric converter according to any one of (14) to (18), in which the first electron transport material and the second electron transport material include same materials.
(20)

The photoelectric converter according to any one of (17) to (19), in which the first electron transport material and the second electron transport material include fullerenes or derivatives thereof.
(21)

The photoelectric converter according to any one of (1) to (20), further including a third photoelectric conversion layer between the first electrode and the second electrode, the third photoelectric conversion layer including a third dye material and a third carrier transport material, the third dye material being different from the first dye material and the second dye material.
(22)

The photoelectric converter according to (21), in which at least one of the first photoelectric conversion layer, the second photoelectric conversion layer, or the third photoelectric conversion layer includes three types of materials including a dye material, a hole transport material, and an electron transport material.
(23)

An imaging device including

a plurality of pixels that is each provided with one or more photoelectric converters, in which

the photoelectric converter includes
a first electrode,
a second electrode that is disposed to be opposed to the first electrode,
a first photoelectric conversion layer that is provided between the first electrode and the second electrode, the first photoelectric conversion layer including a first dye material and a first carrier transport material,
a second photoelectric conversion layer that is stacked on the second electrode side of the first photoelectric conversion layer between the first electrode and the second electrode, the second photoelectric conversion layer including a second dye material and a second carrier transport material, the second dye material having a light absorption waveform different from a light absorption waveform of the first dye material,
a first buffer layer having a first electrical conduction type, the first buffer layer being provided between the first electrode and the first photoelectric conversion layer, and
a second buffer layer having a second electrical conduction type different from the first electrical conduction type, the second buffer layer being provided between the second electrode and the second photoelectric conversion layer.

The present application claims the priority on the basis of Japanese Patent Application No. 2020-098871 filed on Jun. 5, 2020 with Japan Patent Office and Japanese Patent Application No. 2021-89437 filed on May 27, 2021 with Japan Patent Office, the entire contents of which are incorporated in the present application by reference.

It should be understood by those skilled in the art that various modifications, combinations, sub-combinations, and alterations may occur depending on design requirements and other factors insofar as they are within the scope of the appended claims or the equivalents thereof.

1. A photoelectric converter comprising:
a first electrode;
a second electrode that is disposed to be opposed to the first electrode;
a first photoelectric conversion layer that is provided between the first electrode and the second electrode, the first photoelectric conversion layer including a first dye material and a first carrier transport material;
a second photoelectric conversion layer that is stacked on the second electrode side of the first photoelectric conversion layer between the first electrode and the second electrode, the second photoelectric conversion layer including a second dye material and a second carrier transport material, the second dye material having a light absorption waveform different from a light absorption waveform of the first dye material;
a first buffer layer having a first electrical conduction type, the first buffer layer being provided between the first electrode and the first photoelectric conversion layer; and
a second buffer layer having a second electrical conduction type different from the first electrical conduction type, the second buffer layer being provided between the second electrode and the second photoelectric conversion layer.

2. The photoelectric converter according to claim 1, wherein the first photoelectric conversion layer and the second photoelectric conversion layer are directly stacked.

3. The photoelectric converter according to claim 1, wherein the first photoelectric conversion layer and the second photoelectric conversion layer each have an ionization potential of 6 eV or less.

4. The photoelectric converter according to claim 3, wherein the ionization potentials of the first photoelectric conversion layer and the second photoelectric conversion layer have a difference of 0.2 eV or less.

5. The photoelectric converter according to claim 4, wherein
the first buffer layer includes a p-type buffer layer, and
the ionization potential of the first photoelectric conversion layer is less than the ionization potential of the second photoelectric conversion layer.

6. The photoelectric converter according to claim 4, wherein electron affinity of the first photoelectric conversion layer and electron affinity of the second photoelectric conversion layer have a difference of 0.2 eV or less.

7. The photoelectric converter according to claim 1, wherein
the first buffer layer includes a p-type buffer layer, and
the first photoelectric conversion layer has a shallower ionization potential than an ionization potential of the second photoelectric conversion layer.

8. The photoelectric converter according to claim 1, wherein the first dye material and the second dye material have ionization potentials that are substantially same as each other.

9. The photoelectric converter according to claim 1, wherein
the first buffer layer includes a p-type buffer layer, and
the first dye material has a shallower ionization potential than an ionization potential of the second dye material.

10. The photoelectric converter according to claim 1, wherein the first carrier transport material and the second carrier transport material include same materials.

11. The photoelectric converter according to claim 1, wherein the first carrier transport material and the second carrier transport material each include an electron transport material.

12. The photoelectric converter according to claim 1, wherein the first photoelectric conversion layer includes a first hole transport material and a first electron transport material as the first carrier transport materials.

13. The photoelectric converter according to claim 1, wherein the second photoelectric conversion layer includes a second hole transport material and a second electron transport material as the second carrier transport materials.

14. The photoelectric converter according to claim 1, wherein
the first photoelectric conversion layer includes a first hole transport material and a first electron transport material as the first carrier transport materials,
the second photoelectric conversion layer includes a second hole transport material and a second electron transport material as the second carrier transport materials, and
the first hole transport material and the second hole transport material have ionization potentials that are substantially same as each other.

15. The photoelectric converter according to claim 14, wherein
the first buffer layer includes a p-type buffer layer, and
the first hole transport material has a shallower ionization potential than an ionization potential of the second hole transport material.

16. The photoelectric converter according to claim 14, wherein the first hole transport material and the second hole transport material include same materials.

17. The photoelectric converter according to claim 14, wherein the first electron transport material and the second electron transport material have LUMO levels that are substantially same as each other.

18. The photoelectric converter according to claim 14, wherein
the first buffer layer includes a p-type buffer layer, and
the first electron transport material has a shallower LUMO level than a LUMO level of the second electron transport material.

19. The photoelectric converter according to claim 14, wherein the first electron transport material and the second electron transport material include same materials.

20. The photoelectric converter according to claim 17, wherein the first electron transport material and the second electron transport material include fullerenes or derivatives thereof

21. The photoelectric converter according to claim 1, further comprising a third photoelectric conversion layer between the first electrode and the second electrode, the third photoelectric conversion layer including a third dye material and a third carrier transport material, the third dye material being different from the first dye material and the second dye material.

22. The photoelectric converter according to claim 21, wherein at least one of the first photoelectric conversion layer, the second photoelectric conversion layer, or the third photoelectric conversion layer includes three types of materials including a dye material, a hole transport material, and an electron transport material.

23. An imaging device comprising
a plurality of pixels that is each provided with one or more photoelectric converters, wherein
the photoelectric converter includes
a first electrode,
a second electrode that is disposed to be opposed to the first electrode,
a first photoelectric conversion layer that is provided between the first electrode and the second electrode, the first photoelectric conversion layer including a first dye material and a first carrier transport material,
a second photoelectric conversion layer that is stacked on the second electrode side of the first photoelectric conversion layer between the first electrode and the second electrode, the second photoelectric conversion layer including a second dye material and a second carrier transport material, the second dye material having a light absorption waveform different from a light absorption waveform of the first dye material,
a first buffer layer having a first electrical conduction type, the first buffer layer being provided between the first electrode and the first photoelectric conversion layer, and
a second buffer layer having a second electrical conduction type different from the first electrical conduction type, the second buffer layer being provided between the second electrode and the second photoelectric conversion layer.
